(19) United States
(12) Patent Application Publication
(10) Pub. No.: US 2024/0188314 A1
(43) Pub. Date: Jun. 6, 2024

(54) PHOTOELECTRONIC DEVICE AND IMAGE SENSOR, AND ELECTRONIC DEVICE INCLUDING THE SAME

(71) Applicant: Samsung Electronics Co., Ltd., Suwon-si (KR)

(72) Inventors: Insun PARK, Suwon-si (KR); Dong-Seok LEEM, Suwon-si (KR); Rae Sung KIM, Suwon-si (KR); Sangdong KIM, Suwon-si (KR); Sang Ho PARK, Suwon-si (KR)

(73) Assignee: Samsung Electronics Co., Ltd., Suwon-si (KR)

(21) Appl. No.: 18/499,387

(22) Filed: Nov. 1, 2023

(30) Foreign Application Priority Data
Nov. 1, 2022 (KR) 10-2022-0144033

(51) Int. Cl. H10K 30/85; H10K 30/20; H10K 30/81; H10K 30/86; H10K 85/30; H10K 85/60

(52) U.S. Cl. CPC H10K 30/85; H10K 30/211; H10K 30/81; H10K 30/86; H10K 85/30; H10K 85/622; H10K 85/655; H10K 85/6572

(57) ABSTRACT

A photoelectric device includes a first electrode, a second electrode facing the first electrode, an active layer between the first electrode and the second electrode, and an electron auxiliary layer between the second electrode and the active layer, wherein the electron auxiliary layer includes any one compound selected from compounds represented by Chemical Formulas 1 to 4 and any combination thereof.

### CROSS-REFERENCE TO RELATED APPLICATION

This application claims priority to and the benefit of, under 35 U.S.C. § 119, Korean Patent Application No. 10-2022-0144033 filed in the Korean Intellectual Property Office on Nov. 1, 2022, the entire contents of which are incorporated herein by reference.

### BACKGROUND

### 1. Field

Photoelectric devices and sensors and electronic devices including the same are disclosed.

### 2. Description of the Related Art

An imaging device is used in a digital camera and a camcorder, etc., to capture an image and to store it as an electrical signal, and the imaging device includes a sensor separating incident light according to a wavelength and converting each component to an electrical signal.

Recently, sensors in the infra-red region have been researched to improve sensor sensitivity in low-light environments or to be used as biometric or authentication devices.

### SUMMARY

Some example embodiments provide a photoelectric device that has excellent photoelectric conversion efficiency in the infrared wavelength range (near-infrared to short-wave infrared spectrum of about 1000 nm or more), reduces dark current to an appropriate range, and has excellent thermal stability.

Some example embodiments provide a sensor including the photoelectric device.

Some example embodiments provide an electronic device including the photoelectric device.

According to some example embodiments, a photoelectric device includes a first electrode, a second electrode facing the first electrode, an active layer between the first electrode and the second electrode, and an electron auxiliary layer between the second electrode and the active layer, wherein the electron auxiliary layer includes any one compound selected from compounds represented by Chemical Formulas 1 to 4 and any combination thereof.

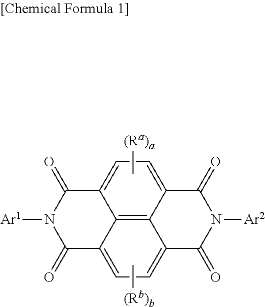

In Chemical Formula 1,
Ar¹ and Ar² may each independently be a substituted or unsubstituted C10 to C30 aryl group or a substituted or unsubstituted C2 to C30 heteroaryl group,
R^{a} and R^{b} may each independently be hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a and b are each independently integers of 1 or 2,

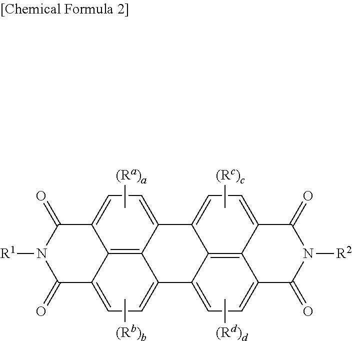

wherein, in Chemical Formula 2,
R¹ and R² may each independently be hydrogen, deuterium, a substituted or unsubstituted C6 to C30 aryl group, or a substituted or unsubstituted C3 to C30 heteroaryl group,
R^{a} to R^{d} may each independently be hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a to d are each independently an integer of 1 or 2,

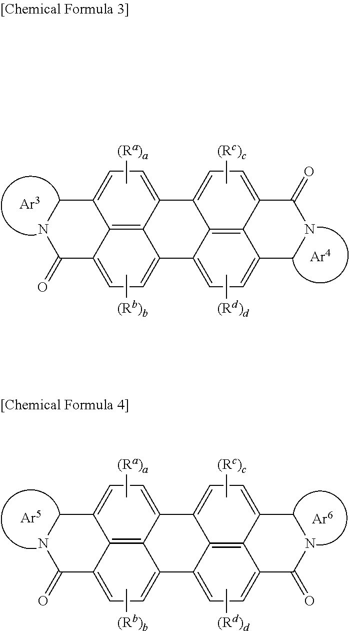

wherein, in Chemical Formulas 3 and 4,
Ar³ to Ar⁶ may each independently be hydrogen, a substituted or unsubstituted C6 to C30 arene group, or a substituted or unsubstituted C3 to C30 heteroarene group,
R^{a} to R^{d} may each independently be hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a to d may each independently be an integer of 1 or 2.

In Chemical Formula 1, Ar¹ and Ar² may each independently be a functional group represented by any one of Chemical Formulas 5A to 5K.

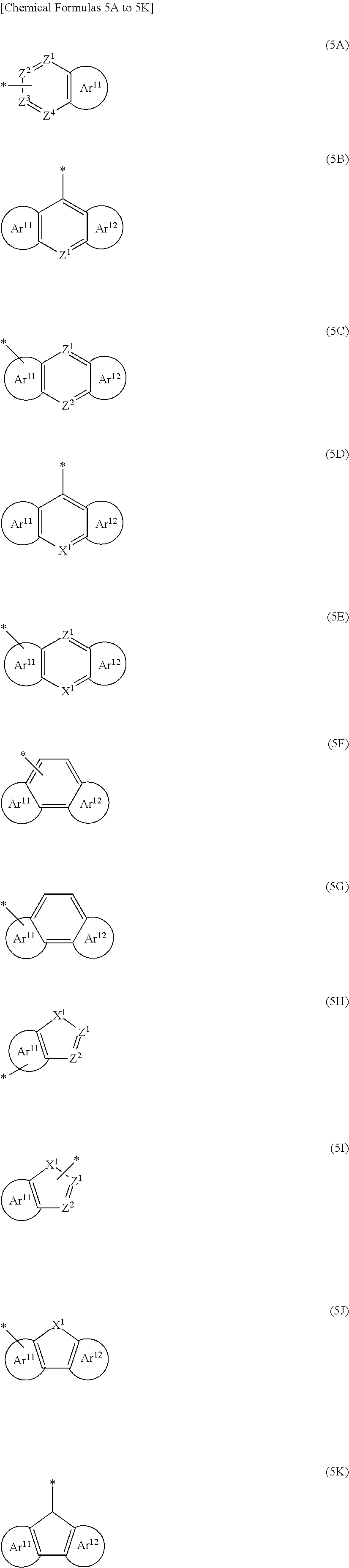

In Chemical Formulas 5A to 5K,
X¹ may be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z⁴ are each independently CR^{x} or N (wherein R^{x} is hydrogen, deuterium, A C1 to C10 alkyl group, a C6 to C14 aryl group, a C3 to C12 heteroaryl group, or any combination thereof), provided that in Chemical Formula 5A, one of Z¹ to Z⁴ is CR^{x} wherein R^{x} is a single bond, and in Chemical Formula 51, one of Z¹ and Z² is CR^{x} wherein R^{x} is a single bond,
Ar¹¹ and Ar¹² are each independently a substituted or unsubstituted C6 to C20 arene group or a substituted or unsubstituted C2 to C20 heteroarene group,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring may be present or may be replaced (e.g., substituted) with —N— (e.g., —CH₂— of the arene group or heteroarene group of Ar¹¹ and Ar¹² may be present or may be replaced by —N—),
* is a linking point with Chemical Formula 1.

In Chemical Formula 1, Ar¹ and Ar² may each independently be a functional group represented by one of Chemical Formulas 6A to 6I.

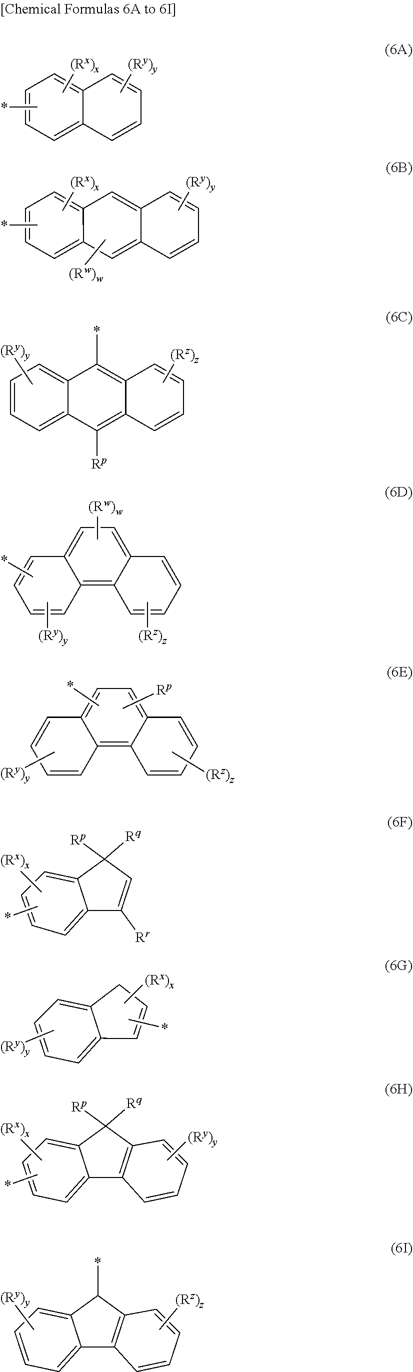

In Chemical Formulas 6A to 6I,
R^{x}, R^{y}, R^{z}, R^{w}, R^{p}, R^{q}, and R^{r} may each independently be hydrogen, deuterium, a C1 to C10 alkyl group, a C6 to C14 aryl group, a C3 to C12 heteroaryl group, or any combination thereof, wherein R^{p} and R^{q} may each independently be present or be linked to each other to form a spiro structure,
x is an integer from 0 to 3,
y and z are each independently integers from 0 to 4,
w is an integer from 0 to 2, and
* is a linking point with Chemical Formula 1.

In Chemical Formula 1, Ar¹ and Ar² may each independently be a functional group represented by one of Chemical Formulas 7A to 7Q.

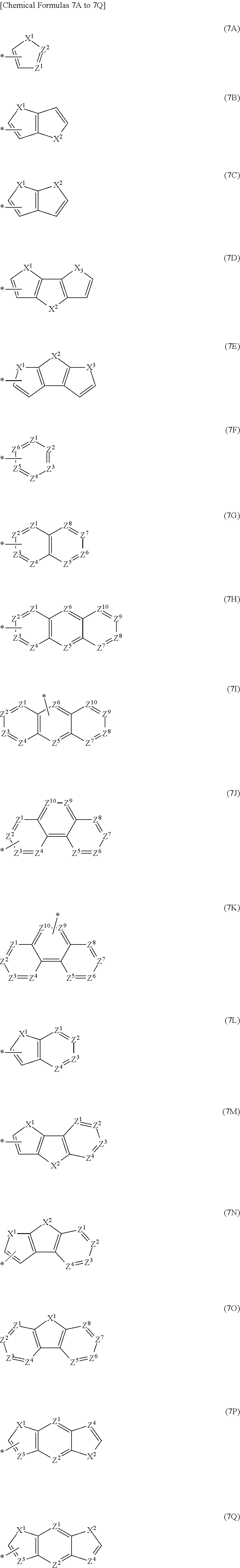

In Chemical Formulas 7A to 7Q,
X¹, X², and X³ may each independently be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z¹⁰ may each independently be CR^{x} or N (wherein R^{x} may be hydrogen, deuterium, a C1 to C10 alkyl group, a C6 to C14 aryl group, a C3 to C12 heteroaryl group, or any combination thereof), provided that when in Chemical Formula 7F, one of Z¹ to Z⁶ is a linking point with Chemical Formula 1, one of Z¹ to Z⁶ is CR^{x} wherein R^{x} is a single bond; when in Chemical Formulas 7G, 7H, 7J, and 70, one of Z¹ to Z⁴ is a linking point with Chemical Formula 1, one of Z¹ to Z⁴ is CR^{x} wherein R^{x} is a single bond; when in Chemical Formula 71, one of Z⁵ to Z⁶ is a linking point with Chemical Formula 1, one of Z⁵ and Z⁶ is CR^{x} wherein R^{x} is a single bond; when in Chemical Formula 7K, one of Z⁹ and Z¹⁰ is a linking point with Chemical Formula 1, one of Z⁹ and Z¹⁰ is CR^{x} wherein R^{x} is a single bond; when in Chemical Formula 7P and 7Q, Z³ is a linking point with Chemical Formula 1, Z³ is CR^{x} wherein R^{x} is a single bond,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring may present or may be replaced by —N—, and
* is a linking point with Chemical Formula 1.

In Chemical Formula 1, Ar¹ and Ar² may each independently be a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyrimidinyl group, a substituted or unsubstituted quinolinyl group, a substituted or unsubstituted isoquinolinyl group, a substituted or unsubstituted quinoxalinyl group, a substituted or unsubstituted quinazolinyl group, a substituted or unsubstituted phenanthrolyl group, a substituted or unsubstituted pyrrolyl group, a substituted or unsubstituted thienyl group, a substituted or unsubstituted indolyl group a substituted or unsubstituted benzimidazolyl group, a substituted or unsubstituted benzthiazolyl group, or a substituted or unsubstituted carbazolyl group.

In Chemical Formula 2, R¹ and R² may be a functional group represented by one of Chemical Formulas 5A to 5L.

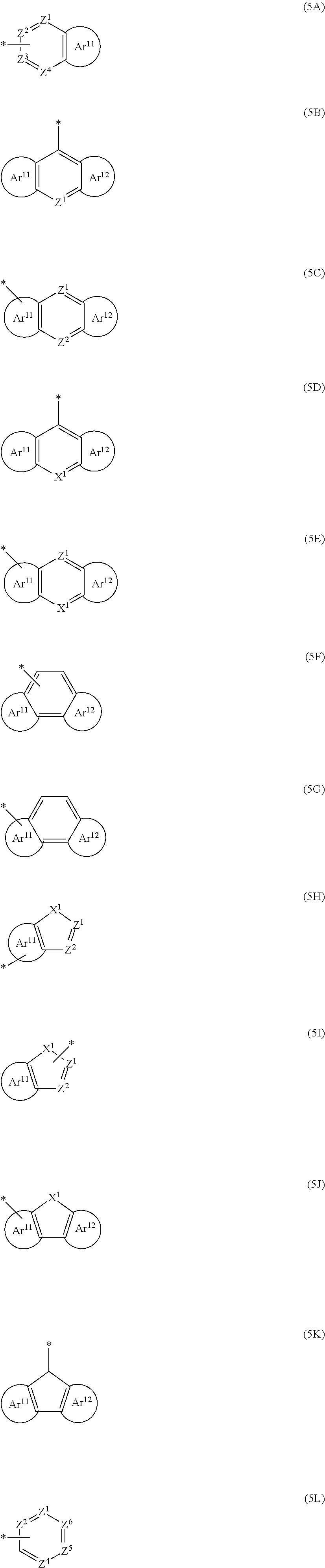

In Chemical Formulas 5A to 5L,
X¹ and X² may each independently be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z⁶ may each independently be CR^{x} or N, wherein R^{x} may be hydrogen, deuterium, a C1 to C10 alkyl group, a C6 to C14 aryl group, a C3 to C12 heteroaryl group, or any combination thereof, provided that in Chemical Formula 5A, one of Z¹ to Z⁴ is CR^{x} wherein R^{x} is a single bond, in Chemical Formula 51, one of Z¹ and Z² is CR^{x} wherein R^{x} is a single bond, and in Chemical Formula 5L, one of Z¹ to Z⁶ is CR^{x} wherein R^{x} is a single bond,
Ar¹¹ and Ar¹² may each independently be a substituted or unsubstituted C6 to C20 arene group or a substituted or unsubstituted C2 to C20 heteroarene group,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring may be present or may be replaced by —N—, and
* is a linking point with Chemical Formula 2.

In Chemical Formula 2, R¹ and R² may each independently be a functional group represented by one of Chemical Formulas 6A to 6J.

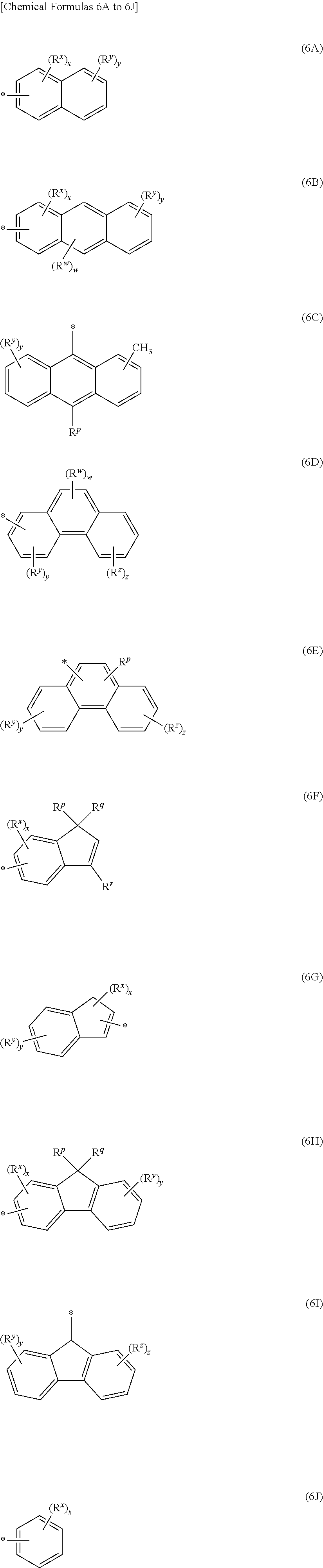

In Chemical Formulas 6A to 6J,
R^{x}, R^{y}, R^{z}, R^{w}, R^{p}, R^{q}, and R^{r} may each independently be hydrogen, deuterium, a C1 to C10 alkyl group, a C6 to C14 aryl group, a C3 to C12 heteroaryl group, or any combination thereof, wherein R^{p} and R^{q} may each independently be present or be linked to each other to form a spiro structure,
x is an integer from 0 to 3,
y and z are each independently integers from 0 to 4,
w is an integer from 0 to 2, and
* is a linking point with Chemical Formula 2.

In Chemical Formula 2, R¹ and R² may each independently be a functional group represented by one of Chemical Formulas 7A to 7Q.

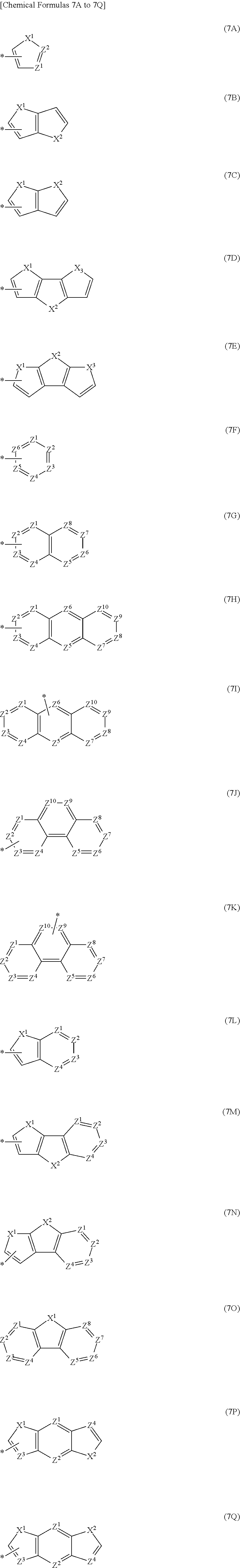

In Chemical Formulas 7A to 7Q,
X¹, X², and X³ may each independently be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z¹⁰ may each independently be CR^{x} or N, wherein R^{x} is hydrogen, deuterium, a C1 to C10 alkyl group, a C6 to C14 aryl group, a C3 to C12 heteroaryl group, or any combination thereof, provided that when in Chemical Formula 7F, one of Z¹ to Z⁶ is a linking point with Chemical Formula 2, one of Z¹ to Z⁶ is CR^{x} wherein R^{x} is a single bond; when in Chemical Formulas 7G, 7H, 7J, and 70, one of Z¹ to Z⁴ is a linking point with Chemical Formula 2, one of Z¹ to Z⁴ is CR^{x} wherein R^{x} is a single bond; when in Chemical Formula 71, one of Z⁵ to Z⁶ is a linking point with Chemical Formula 2, one of Z⁵ and Z⁶ is CR^{x} wherein R^{x} is a single bond; when in Chemical Formula 7K, one of Z⁹ and Z¹⁰ is a linking point with Chemical Formula 2, one of Z⁹ and Z¹⁰ is CR^{x} wherein R^{x} is a single bond; when in Chemical Formulas 7P and 7Q, Z³ is a linking point with Chemical Formula 2, Z³ is CR^{x} wherein R^{x} is a single bond,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring may be present or may be replaced by —N—, and
* is a linking point with Chemical Formula 2.

In Chemical Formula 2, R¹ and R² may each independently be a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyrimidinyl group, a substituted or unsubstituted quinolinyl group, a substituted or unsubstituted isoquinolinyl group, a substituted or unsubstituted quinoxalinyl group, a substituted or unsubstituted quinazolinyl group, a substituted or unsubstituted phenanthrolyl group, a substituted or unsubstituted pyrrolyl group, a substituted or unsubstituted thienyl group, a substituted or unsubstituted indolyl group a substituted or unsubstituted benzimidazolyl group, a substituted or unsubstituted benzthiazolyl group, or a substituted or unsubstituted carbazolyl group.

The compound of Chemical Formula 3 may be a compound represented by any one of Chemical Formulas 3-1 to 3-9.

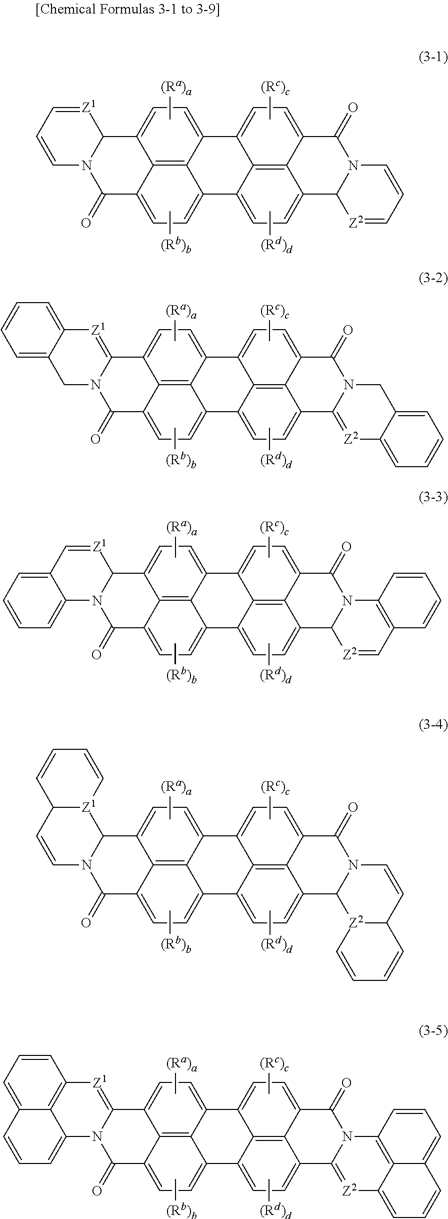

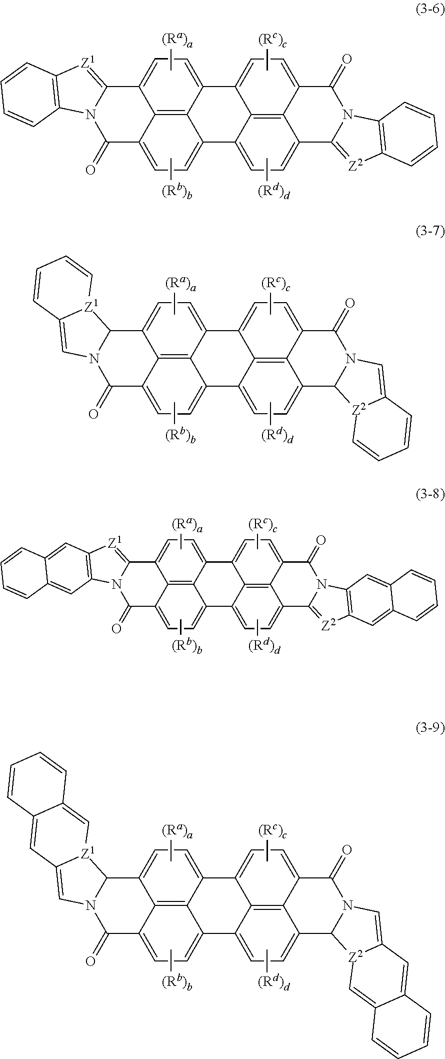

In Chemical Formulas 3-1 to 3-9,
R^{a}, R^{b}, R^{c}, R^{d}, a, b, c, and d are the same as R^{a}, R^{b}, R^{c}, R^{d}, a, b, c, and d, respectively, in Chemical Formula 3,
Z¹ and Z² are each independently CR^{x} or N, wherein R^{x} is hydrogen, deuterium, A C1 to C10 alkyl group, a C6 to C14 aryl group, a C3 to C12 heteroaryl group, or any combination thereof,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof, and
at least one —CH₂— of each aromatic ring or heteroaromatic ring may be present or may be replaced by —N—.

The compound of Chemical Formula 4 may be a compound represented by any one of Chemical Formulas 4-1 to 4-9.

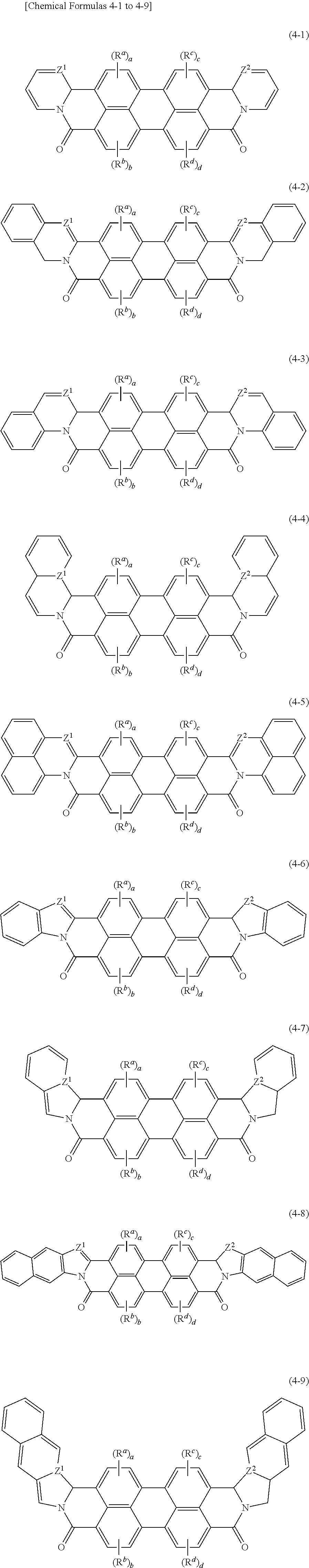

In Chemical Formulas 4-1 to 4-9,
R^{a}, R^{b}, R^{c}, R^{d}, a, b, c, and d are the same as R^{a}, R^{b}, R^{c}, R^{d}, a, b, c, and d, respectively, in Chemical Formula 4,
Z¹ and Z² are each independently CR^{x} or N, wherein R^{x} is hydrogen, deuterium, a C1 to C10 alkyl group, a C6 to C14 aryl group, a C3 to C12 heteroaryl group, or any combination thereof,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof, and
at least one —CH₂— of each aromatic ring or heteroaromatic ring may be present or may be replaced by —N—.

The electron auxiliary layer may be an electron transport layer.

The active layer may be an infrared photoelectric conversion layer that is configured to absorb light in at least a portion of an infrared wavelength range and convert the absorbed light into an electrical signal.

The active layer may include a metal phthalocyanine complex, a metal naphthalocyanine complex, or a compound including a quinoid moiety.

The photoelectric device may further include a hole auxiliary layer between the first electrode and the active layer.

The first electrode may include a reflective layer, and the second electrode may include a semi-transmissive layer that forms a microcavity structure with the reflective layer of the first electrode.

The first electrode may have a stacked structure of a reflective layer/light-transmitting layer or a first light-transmitting layer/reflective layer/second light-transmitting layer.

According to some example embodiments, a sensor including the photoelectric device is provided.

According to some example embodiments, an electronic device including the photoelectric device is provided.

A photoelectric device with improved optical properties such as photoelectric conversion efficiency, reduced dark current, and improved thermal stability may be provided.

### BRIEF DESCRIPTION OF THE DRAWINGS

FIG. 1 is a cross-sectional view showing a photoelectric device according to some example embodiments,

FIG. 2 is a cross-sectional view of a sensor according to some example embodiments,

FIG. 3 is a cross-sectional view of a sensor according to some example embodiments,

FIG. 4 is a schematic perspective view of a sensor according to some example embodiments,

FIG. 5 is a schematic cross-sectional view of the sensor of FIG. 4 along view line V-V′ in FIG. 4,

FIG. 6 is a schematic perspective view of a sensor according to some example embodiments,

FIG. 7 is a schematic cross-sectional view of the sensor of FIG. 6, and

FIG. 8 is a schematic view illustrating an example of the configuration of an electronic device according to some example embodiments.

### DETAILED DESCRIPTION

Hereinafter, some example embodiments will hereinafter be described in detail, and may be easily performed by a person having an ordinary skill in the related art. However, the inventive concepts may be embodied in many different forms and are not to be construed as limited to the example embodiments set forth herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity of the embodiments, and the same or similar constituent elements are indicated by the same reference numeral throughout the specification.

Hereinafter, the terms “lower” and “upper” are used for better understanding and ease of description, but do not limit the location relationship.

As used herein, when a definition is not otherwise provided, “substituted” refers to replacement of hydrogen of a compound by a substituent selected from a halogen, a hydroxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a C1 to C30 alkyl group, a C2 to C30 alkenyl group, a C2 to C30 alkynyl group, a C6 to C30 aryl group, a C7 to C30 arylalkyl group, a C1 to C30 alkoxy group, a C1 to C20 heteroalkyl group, a C3 to C20 heterocyclic group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

As used herein, when a definition is not otherwise provided, the term “combination of functional groups or moieties” refers to at least two substituents bound to each other by a single bond or a C1 to C10 alkylene group, or at least two fused substituents.

Additionally, “combination” may refer to a mixture or a stacked structure of constituent components.

As used herein, when a definition is not otherwise provided, “hetero” refers to one including 1 to 4 heteroatoms selected from N, O, S, Se, Te, Si, and P.

As used herein, when a definition is not otherwise provided, “alkyl group” may be a linear or branched saturated monovalent hydrocarbon group (e.g., a methyl group, an ethyl group, a propyl group, an isobutyl group, a sec-butyl group, a tert-butyl group, a pentyl group, an iso-amyl group, a hexyl group, and the like).

As used herein, when a definition is not otherwise provided, “alkoxy group” may refer to a linear or branched, monovalent hydrocarbon group (e.g., ethenyl group) having at least one carbon-carbon double bond.

As used herein, when a definition is not otherwise provided, “alkoxy group” may refer to an alkyl group that is linked via an oxygen, e.g., a methoxy group, an ethoxy group, and a sec-butyloxy group.

As used herein, when a definition is not otherwise provided, “aryl group” refers to a monovalent functional group formed by the removal of one hydrogen atom from one or more rings of an arene, e.g., phenyl or naphthyl. The arene refers to a hydrocarbon having an aromatic ring, and includes monocyclic and polycyclic hydrocarbons wherein the additional ring(s) of the polycyclic hydrocarbon may be aromatic or nonaromatic.

As used herein, when a definition is not otherwise provided, “arene group” refers to a hydrocarbon group having an aromatic ring, and includes monocyclic and polycyclic hydrocarbon groups, and the additional ring of the polycyclic hydrocarbon group may be an aromatic ring or a nonaromatic ring. “Heteroarene group” refers to an arene group including 1 to 3 heteroatoms selected from N, O, S, Se, Te, P, and Si in a ring group.

As used herein, when a definition is not otherwise provided, “heterocyclic group” is a higher concept of a heteroaryl group, and may include at least one heteroatom selected from N, O, S, Se, Te, P and Si, and the remaining carbon. When the heterocyclic group is a fused ring, the entire heterocyclic group or each ring may include one or more heteroatoms.

As used herein, when a definition is not otherwise provided, “aromatic ring” or “heteroaromatic ring” refers to a functional group in which all ring-forming atoms in the cyclic functional group have a p-orbital, and wherein these p-orbitals are conjugated. For example, “aromatic ring” or “heteroaromatic ring” may refer to a C6 to C30 aryl group or a C3 to C30 heteroaryl group.

As used herein, when a definition is not otherwise provided, “fused ring” may be a ring in which two or more aromatic rings (arene rings or heteroarene rings) are fused, or a ring in which an aromatic ring (arene ring or heteroarene ring) and a non-aromatic ring (alicyclic ring) are fused. For example, at least one aromatic ring (arene ring or heteroarene ring) such as at least one arene ring (such as a C6 to C30 arene group, a C6 to C20 arene group, or a C6 to C10 arene group) and/or at least one heteroarene ring (such as a C2 to C30 heteroarene group, a C2 to C20 heteroarene group, or a C2 to C10 heteroarene group) and at least one non-aromatic ring (alicyclic ring, such as a C3 to C30 cycloalkyl group, a C3 to C20 cycloalkyl group or a C3 to C10 Cycloalkyl groups) may be fused to each other.

As used herein, when a definition is not otherwise provided, “spiro structure” may be a substituted or unsubstituted C5 to C30 hydrocarbon cyclic group, a substituted or unsubstituted C2 to C30 heterocyclic group, or a fused ring thereof. The substituted or unsubstituted C5 to C30 hydrocarbon cyclic group may be for example a substituted or unsubstituted C5 to C30 cycloalkyl group (e.g., a substituted or unsubstituted C5 to C20 cycloalkyl group or a substituted or unsubstituted C5 to C10 cycloalkyl group) or a substituted or unsubstituted C6 to C30 aryl group (e.g., a substituted or unsubstituted C6 to C20 aryl group, or a substituted or unsubstituted C6 to C10 aryl group) and the substituted or unsubstituted C2 to C30 heterocyclic group may be for example a substituted or unsubstituted C2 to C20 heterocycloalkyl group (e.g., a substituted or unsubstituted C2 to C10 heterocycloalkyl group) or a substituted or unsubstituted C2 to C20 heteroaryl group (e.g., a substituted or unsubstituted C2 to C10 heteroaryl group).

It will further be understood that when an element is referred to as being “on” another element, it may be above or beneath or adjacent (e.g., horizontally adjacent) to the other element. It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%). Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%). It will be understood that elements and/or properties thereof may be recited herein as being “the same” or “equal” as other elements and/or properties thereof, and it will be further understood that elements and/or properties thereof recited herein as being “identical” to, “the same” as, or “equal” to other elements and/or properties thereof may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof. While the term “same,” “equal” or “identical” may be used in description of some example embodiments, it should be understood that some imprecisions may exist. Thus, when one element is referred to as being the same as another element, it should be understood that an element or a value is the same as another element or value within a desired manufacturing or operational tolerance range (e.g., ±10%). When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-2 (Hitachi) or AC-3 (Riken Keiki Co., Ltd.).

Hereinafter, when a definition is not otherwise provided, the LUMO energy level may be obtained by obtaining a bandgap energy using a UV-Vis spectrometer (Shimadzu Corporation), and then calculating the LUMO energy level from the bandgap energy and the already measured HOMO energy level.

Hereinafter, the wavelength at the point where the light absorption is maximum in the optical absorption spectrum is referred to as “maximum absorption wavelength,” and the wavelength at the point where the external quantum efficiency (EQE) is maximum in the external quantum efficiency spectrum (EQE spectrum) is referred to as “maximum external quantum efficiency wavelength” or “maximum EQE wavelength.”

Under the same conditions, the maximum external quantum efficiency wavelength or the maximum EQE wavelength may be the same as the maximum absorption wavelength, and may be mixed.

Hereinafter, the infrared light may be light in at least a portion of a near infrared wavelength region, a short wave infrared wavelength region, a mid wave infrared wavelength region, and a far wave infrared wavelength region and the infrared wavelength region infrared wavelength region may, for example, belong to about 1000 nm to about 3000 nm, within the above range, for example about 1050 nm to about 3000 nm, about 1050 nm to about 2500 nm, about 1050 nm to about 2300 nm, about 1050 nm to about 2000 nm, about 1050 nm to about 1800 nm, about 1050 nm to about 1700 nm, about 1100 nm to about 3000 nm, about 1100 nm to about 2500 nm, about 1100 nm to about 2300 nm, about 1100 nm to about 2000 nm, about 1100 nm to about 1800 nm or about 1100 nm to about 1700 nm.

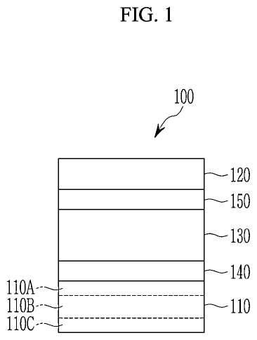

Hereinafter, a photoelectric device according to some example embodiments will be described with reference to FIG. 1. FIG. 1 is a cross-sectional view showing an example of a photoelectric device according to some example embodiments.

Referring to FIG. 1, the photoelectric device 100 according to some example embodiments includes a first electrode 110, a second electrode 120 facing the first electrode 110, an active layer 130 between the first electrode 110 and the second electrode 120, a hole auxiliary layer 140 between the first electrode 110 and the active layer 130, and an electron auxiliary layer 150 between the second electrode 120 and the active layer 130. The hole auxiliary layer 140 may include a compound with excellent hole transport properties, and the electron auxiliary layer 150 may include a compound with excellent electron transport properties, which will be described later. For example, the electron auxiliary layer 150 may be an electron transport layer (ETL) as described herein.

A substrate (not shown) may be disposed under the first electrode 110 or on the second electrode 120. The substrate may be for example an inorganic substrate such as a glass plate or silicon wafer or an organic substrate made of an organic material such as polycarbonate, polymethylmethacrylate, polyethyleneterephthalate, polyethylenenaphthalate, polyamide, polyethersulfone, or any combination thereof. The substrate may be omitted.

The substrate may be, for example, a semiconductor substrate, or a silicon substrate. The semiconductor substrate may include a circuit unit (not shown) including for example circuitry, and the circuit unit (e.g., circuitry) may include transmission transistors (not shown) and/or charge storage (not shown) integrated in the semiconductor substrate. The circuit unit may be electrically connected to the first electrode 110 or the second electrode 120.

One of the first electrode 110 or the second electrode 120 may be an anode and the other may be a cathode. For example, the first electrode 110 may be an anode and the second electrode 120 may be a cathode. For example, the first electrode 110 may be a cathode and the second electrode 120 may be an anode.

At least one of the first electrode 110 or the second electrode 120 may be a light-transmitting electrode. The light-transmitting electrode may be a transparent electrode or a semi-transmissive electrode. The transparent electrode may have a light transmittance of greater than or equal to about 85%, greater than or equal to about 90%, or greater than or equal to about 95% and the semi-transmissive electrode may have a light transmittance of greater than or equal to about 30% and less than about 85%, about 40% to about 80%, or about 40% to about 75%. The transparent electrode and the semi-transmissive electrode may include, for example, at least one of an oxide conductor, a carbon conductor, or a metal thin film. The oxide conductors may include, for example, one or more selected from indium tin oxide (ITO), indium zinc oxide (IZO), zinc tin oxide (ZTO), aluminum tin oxide (ATO), and aluminum zinc oxide (AZO), the carbon conductor may include one or more selected from graphene and carbon nanostructures, and the metal thin film may be a very thin film including aluminum (Al), magnesium (Mg), silver (Ag), gold (Au), magnesium-silver (Mg—Ag), magnesium-aluminum (Mg—Al), an alloy thereof, or any combination thereof.

At least one of the first electrode 110 or the second electrode 120 may be a reflective electrode. The reflective electrode may include a reflective layer having a light transmittance of less than or equal to about 5% and/or a reflectance of greater than or equal to about 80%, and the reflective layer may include an optically opaque material. The optically opaque material may include a metal, a metal nitride, or any combination thereof, for example silver (Ag), copper (Cu), aluminum (Al), gold (Au), titanium (Ti), chromium (Cr), nickel (Ni), an alloy thereof, a nitride thereof (e.g., TiN), or any combination thereof, but is not limited thereto.

The reflective electrode may include (e.g., may be formed of) a reflective layer or may have a stacked structure of a reflective layer/transmissive layer 110A or a transmissive layer/reflective layer/transmissive layer (e.g., a first light-transmitting layer 110A/reflective layer 110B/second light-transmitting layer 110C), and the reflective layer may be one layer or two or more layers.

The reflective layer may have high reflectance and low light transmittance, and may have, for example, a light transmittance of about 10% to about 100%, about 20% to about 100%, about 30% to about 100%, about 50% to about 100%, about 70% to about 100%, about 80% to about 100%, about 90% to about 100%, about 95% to about 100%, about 98% to about 100%, or about 99% to about 100%, for example greater than or equal to about 0% to less than about 10%, about 0% to about 8%, about 0% to about 7%, about 0% to about 5%, about 0% to about 3%, or about 0% to about 1%. The reflective layer may include an optically opaque material, for example, a metal, a metal nitride, or any combination thereof, for example, silver (Ag), copper (Cu), aluminum (Al), gold (Au), titanium (Ti), chromium (Cr), nickel (Ni), alloys thereof, nitrides thereof (e.g., TiN), or any combination thereof, but is not limited thereto.

The light-transmitting layer, first light-transmitting layer, and second light-transmitting layer may have, for example, a relatively high light transmittance of about 80% to about 100%, about 85% to about 100%, about 88% to about 100%, or about 90% to about 100%. The light-transmitting layer, first light-transmitting layer, and second light-transmitting layer may include an optically transparent conductor, for example, may include at least one of an oxide conductor, a carbon conductor, and a metal thin film. The oxide conductors may include, for example, one or more selected from indium tin oxide (ITO), indium zinc oxide (IZO), zinc tin oxide (ZTO), aluminum tin oxide (ATO) and aluminum zinc oxide (AZO), the carbon conductor may include one or more selected from graphene and carbon nanomaterials, and the metal thin film may include, for example, a metal thin film formed to a thin thickness of several nanometers to several tens of nanometers, or a single layer or a plurality of metal thin films formed to a thin thickness of several nanometers to several tens of nanometers doped with metal oxide.

In the first light-transmitting layer/reflective layer/second light-transmitting layer, a thickness of the first light-transmitting layer may be, for example less than or equal to about 30 nm, less than or equal to about 25 nm, or less than or equal to about 20 nm, within the above range, about 2 nm to about 30 nm, about 2 nm to about 25 nm, or about 2 nm to about 20 nm, but is not limited thereto.

In the first light-transmitting layer/reflective layer/second light-transmitting layer, a thickness of the reflective layer may be, for example less than or equal to about 150 nm, less than or equal to about 140 nm, less than or equal to about 130 nm, less than or equal to about 120 nm, or less than or equal to about 110 nm, and greater than or equal to about 85 nm or greater than or equal to about 90 nm, but is not limited thereto.

In the first light-transmitting layer/reflective layer/second light-transmitting layer, a thickness of the second light-transmitting layer may be, for example less than or equal to about 70 nm, less than or equal to about 60 nm, or less than or equal to about 50 nm, and within the above range, about 5 nm to about 70 nm, about 5 nm to about 60 nm, or about 5 nm to about 50 nm, but is not limited thereto.

The second electrode may include a semi-transmissive layer forming (e.g., defining) a microcavity structure with the reflective layer of the first electrode, and a peak wavelength of the external quantum efficiency (EQE) spectrum of the photoelectric device may correspond to the resonance wavelength of the microcavity structure.

The semi-transmissive layer may have a light transmittance between the light-transmitting layer and the reflective layer, and for example, may have a light transmittance of about 10% to about 70%, about 20% to about 60%, or about 30% to about 50%. The semi-transmissive layer may selectively transmit light in a predetermined wavelength region and reflect or absorb light in other wavelength regions. The semi-transmissive layer may include, for example, a metal layer or an alloy layer having a relatively thin thickness of about 5 nm to about 40 nm, and may include, for example, silver (Ag), copper (Cu), aluminum (Al), magnesium (Mg), magnesium-silver (Mg—Ag), magnesium-aluminum (Mg—Al), or any combination thereof, but is not limited thereto. A thickness of the semi-transmissive layer may be, for example, less than or equal to about 80 nm, less than or equal to about 70 nm, less than or equal to about 60 nm, less than or equal to about 50 nm, or less than or equal to about 40 nm, within the above range, about 5 nm to about 80 nm, about 5 nm to about 70 nm, about 5 nm to about 60 nm, about 5 nm to about 50 nm, about 5 nm to about 40 nm, about 10 nm to about 80 nm, about 10 nm to about 70 nm, about 10 nm to about 60 about nm, about 10 nm to about 50 nm, about 10 nm to about 40 nm, about 20 nm to about 80 nm, about 20 nm to about 70 nm, about 20 nm to about 60 nm, about 20 nm to about 50 nm, or about 20 nm to about 40 nm, but is not limited thereto.

For example, each of the first electrode 110 and the second electrode 120 may be a light-transmitting electrode, and any one of the first electrode 110 or the second electrode 120 may be a light-receiving electrode disposed on the light receiving side.

For example, the first electrode 110 may be a light-transmitting electrode, the second electrode 120 may be a reflective electrode, and the first electrode 110 may be a light-receiving electrode.

For example, the first electrode 110 may be a reflective electrode, the second electrode 120 may be a light-transmitting electrode, and the second electrode 120 may be a light-receiving electrode.

The photoelectric device 100 includes an active layer 130 between the first electrode 110 and the second electrode 120 and an electron auxiliary layer 150 between the active layer 130 and the second electrode 120.

The active layer 130 may absorb light of at least a portion of the infrared wavelength region and convert it (the absorbed light) into an electrical signal. For example, the active layer 130 may be an infrared photoelectric conversion layer that is configured to absorb light (e.g., incident light) in at least a portion of an infrared wavelength range and convert the absorbed light into an electrical signal.

The active layer 130 includes an infrared absorbing material capable of photoelectric conversion by selectively absorbing at least a portion of light in an infrared wavelength region. The infrared absorbing material may be, for example, an organic material, an inorganic material, an organic-inorganic material, or any combination thereof. For example, the infrared absorbing material may be an organic material, for example, may be a non-polymer or a polymer.

Herein, the selective absorption of at least a portion of the light in the infrared wavelength range means that a maximum absorption wavelength (Amax) of the absorption spectrum exists in one of the wavelength ranges of about 1000 nm to about 3000 nm, and that the absorption spectrum in the corresponding wavelength region is significantly higher than that of other wavelength regions. Herein, the “significantly higher” may mean that about 70% to about 100%, about 75% to about 100%, about 80% to about 100%, about 85% to about 100%, about 90% to about 100%, or about 95% to about 100% of the total area of the absorption spectrum may belong to the corresponding wavelength region.

The active layer 130 may include at least one p-type semiconductor and at least one n-type semiconductor for photoelectric conversion of the absorbed light. The p-type semiconductor and the n-type semiconductor may form a pn junction, generate excitons by receiving light from the outside, and then separate the generated excitons into holes and electrons.

At least one of the p-type semiconductor or the n-type semiconductor may be a light absorbing material, and for example, each of the p-type semiconductor or the n-type semiconductor may be a light absorbing material. For example, at least one of the p-type semiconductor or the n-type semiconductor may be an organic material. For example, at least one of the p-type semiconductor or the n-type semiconductor may be a wavelength-selective light absorbing material configured to selectively absorb light in a particular (or, alternatively, predetermined) wavelength region. For example, the p-type semiconductor and the n-type semiconductor may have the maximum absorption wavelength (Amax) in the same or different wavelength region.

In some example embodiments, the p-type semiconductor may include a metal phthalocyanine complex or a metal naphthalocyanine complex, and the n-type semiconductor may include fullerene or a fullerene derivative. Herein, the metal may be copper (Cu), tin (Sn), cobalt (Co), iron (Fe), nickel (Ni), zinc (Zn), magnesium (Mg), or any combination thereof, but is not limited thereto.

In some example embodiments, the p-type semiconductor may include a coplanar compound having at least one quinoid moiety, and the n-type semiconductor may include fullerene or a fullerene derivative.

The coplanar compound having at least one quinoid moiety may be a compound that contains a moiety capable of providing electron donating properties and a moiety capable of providing electron accepting properties together with a moiety having high planarity, thereby forming a very large dipole moment. The coplanar compound having at least one quinoid moiety may be, for example, a compound having at least one quinoid moiety, a moiety capable of providing an electron donating property bound to one terminal end of the quinoid moiety, and a moiety capable of providing an electron accepting property bound to the other terminal end of the quinoid moiety.

The coplanar compound having at least one quinoid moiety may be represented by Chemical Formula 8.

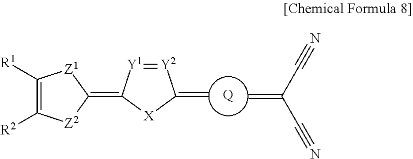

In Chemical Formula 8,
X is O, S, Se, Te, SO, SO₂, NR^{a}, CR^{b}R^{c}, or SiR^{d}R^{e},
Y¹ and Y² are each independently CR^{f} or N,
Z¹ and Z² are each independently O, S, Se, Te, or NR^{g},
Q is at least one substituted or unsubstituted 5-membered quinoid ring, at least one substituted or unsubstituted 6-membered quinoid ring, or a fused ring thereof,
R¹ and R² are each independently hydrogen, a substituted or unsubstituted C1 to C30 alkyl group, a substituted or unsubstituted C1 to C30 alkoxy group, a substituted or unsubstituted C1 to C30 thioalkoxy group, a substituted or unsubstituted C6 to C30 aryl group, a substituted or unsubstituted C3 to C30 heterocyclic group, a substituted or unsubstituted silyl group, a halogen, or any combination thereof,
R^{a} to R^{g} are each independently hydrogen, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heterocyclic group, a substituted or unsubstituted silyl group, a halogen, a cyano group, or any combination thereof,
R¹ and R² are each independently present or combine with each other to form a ring,
R^{b} and R^{c} are each independently present or combine with each other to form a ring,
R^{d} and R^{e} are each independently present or combine with each other to form a ring, and
adjacent R^{f}'s are each independently present or combine with each other to form a ring.

For the coplanar compound having the quinoid moiety, the compound described in Korean Patent Application No. 2021-0083800, published as Korean Patent Publication No. KR-2023-0001181-A, may be referred and the description of such compound therein is incorporated by reference herein.

The active layer 130 may be an intrinsic layer (I-layer) in which a p-type semiconductor and an n-type semiconductor are mixed in a bulk heterojunction form. Herein, the p-type semiconductor and the n-type semiconductor may be mixed in a volume ratio (thickness ratio) of about 1:1 to about 1:10, within the above range, about 1:1 to about 1:9, about 1:1 to about 1:8.5, about 1:1 to about 1:8, about 1:1 to about 1:7.5, about 1:1 to about 1:7, about 1:1 to about 1:6.5, or about 1:1 to about 1:6.

Alternatively, the active layer 130 may include a bi-layer including a p-type layer including a p-type semiconductor and an n-type layer including an n-type semiconductor. At this time, a thickness ratio of the p-type layer and the n-type layer may be about 1:1 to about 1:10, and within the above range, for example, about 1:1 to about 1:9, about 1:1 to about 1:8.5, about 1:1 to about 1:8, about 1:1 to about 1:7.5, about 1:1 to about 1:7, about 1:1 to about 1:6.5, or about 1:1 to about 1:6.

The active layer 130 may further include a p-type layer and/or an n-type layer in addition to the intrinsic layer. The p-type layer may include the aforementioned p-type semiconductor and the n-type layer may include the aforementioned n-type semiconductor. For example, the active layer 130 may be included in various combinations such as p-type layer/I layer, I layer/n-type layer, p-type layer/I layer/n-type layer, etc.

The active layer 130 may have a thickness of about 10 nm to about 500 nm, and within the above range, about 20 nm to about 300 nm. Within the above thickness range, photoelectric conversion efficiency may be effectively improved by effectively absorbing light and effectively separating and transferring holes and electrons.

The electron auxiliary layer 150 includes any one compound selected from compounds represented by Chemical Formulas 1 to 4 and any combination thereof.

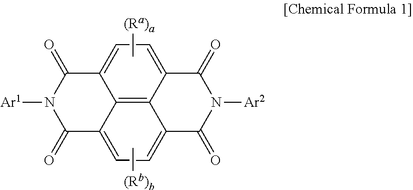

In Chemical Formula 1,
Ar¹ and Ar² may each independently be a substituted or unsubstituted C10 to C30 aryl group or a substituted or unsubstituted C2 to C30 heteroaryl group,
R^{a} and R^{b} may each independently be hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a and b may each independently be integers of 1 or 2,

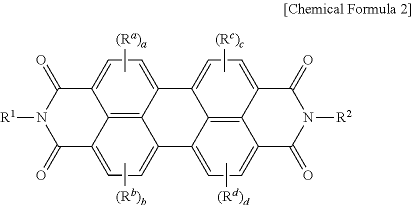

wherein, in Chemical Formula 2,
R¹ and R² may each independently be hydrogen, deuterium, a substituted or unsubstituted C6 to C30 aryl group, or a substituted or unsubstituted C3 to C30 heteroaryl group,
R^{a} to R^{d} may each independently be hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a to d may each independently be an integer of 1 or 2,

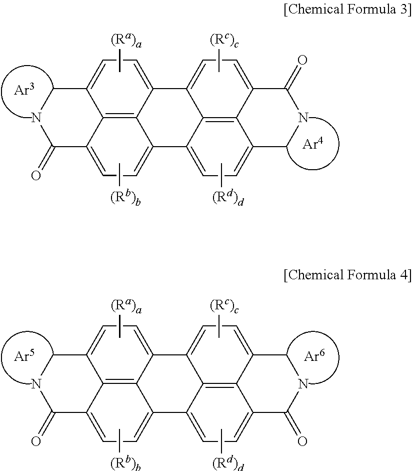

wherein, in Chemical Formulas 3 and 4,
Ar³ to Ar⁶ may each independently be hydrogen, a substituted or unsubstituted C6 to C30 arene group, or a substituted or unsubstituted C3 to C30 heteroarene group,
R^{a} to R^{d} may each independently be hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a to d may each independently be an integer of 1 or 2.

In Chemical Formula 1, when Ar¹ and Ar² are an alkyl group or a cycloalkyl group, a desired level of photoelectric conversion efficiency cannot be obtained in the infrared wavelength range.

In Chemical Formula 1, Ar¹ and Ar² may be the same or different from each other.

In Chemical Formula 1, Ar¹ and Ar² may each independently be a functional group represented by any one of Chemical Formulas 5A to 5K.

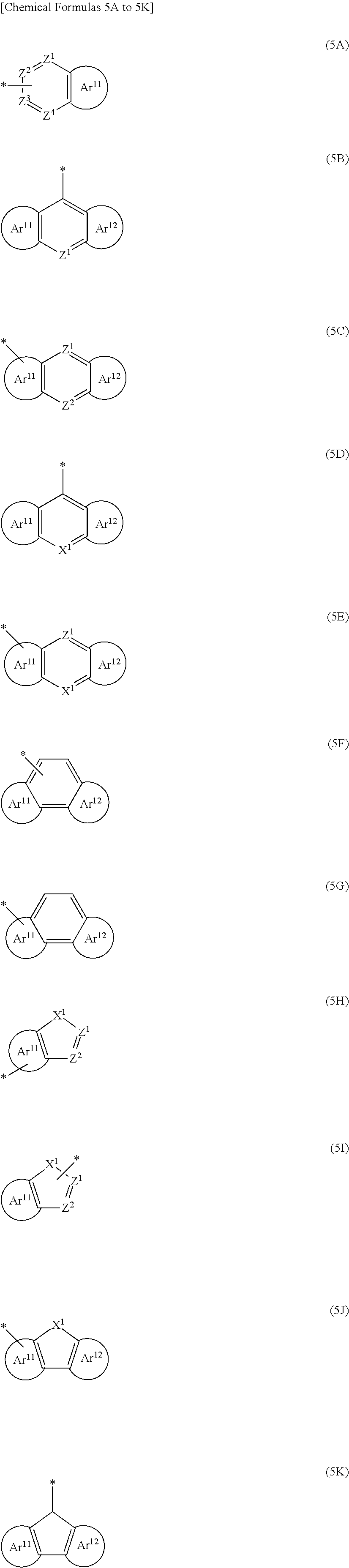

In Chemical Formulas 5A to 5K,
X¹ may be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z⁴ are each independently CR^{x} or N (wherein R^{x} is hydrogen, deuterium, A C1 to C10 alkyl group, a C6 to C14 aryl group, a C3 to C12 heteroaryl group, or any combination thereof), provided that in Chemical Formula 5A, one of Z¹ to Z⁴ is CR^{x} wherein R^{x} is a single bond, and in Chemical Formula 51, one of Z¹ and Z² is CR^{x} wherein R^{x} is a single bond,
Ar¹¹ and Ar¹² may each independently be a substituted or unsubstituted C6 to C20 arene group (e.g., a substituted or unsubstituted C6 to C14 arene group) or a substituted or unsubstituted C2 to C20 heteroarene group (e.g., a substituted or unsubstituted C2 to C10 heteroarene group),
hydrogen of each aromatic ring or heteroaromatic ring may be replaced by deuterium, a C1 to C10 alkyl group, a C1 to C10 alkoxy group, a C6 to C10 aryl group, a C6 to C10 aryloxy group, or any combination thereof (e.g., at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof),
CH₂— of each aromatic ring or heteroaromatic ring may be replaced by —N— (e.g., at least one —CH₂— of each aromatic ring or heteroaromatic ring may be present or may be replaced by —N—), and
* is a linking point with Chemical Formula 1.

In Chemical Formula 1, Ar¹ and Ar² may each independently be a functional group represented by one of Chemical Formulas 6A to 6I.

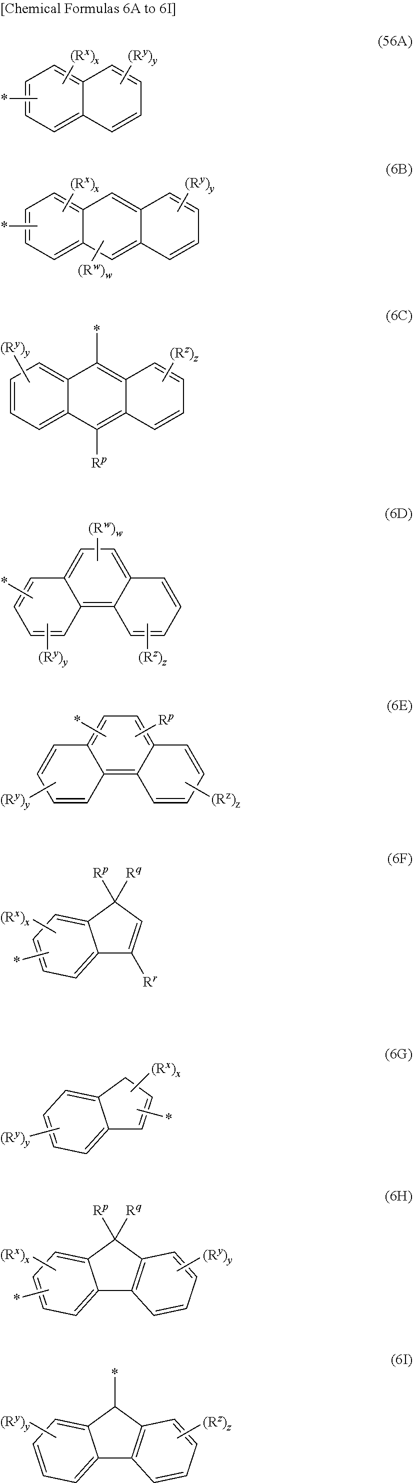

In Chemical Formulas 6A to 6I,
R^{x}, R^{y}, R^{z}, R^{w}, R^{p}, R^{q}, and R^{r} may each independently be hydrogen, deuterium, a C1 to C10 alkyl group, a C6 to C14 aryl group, a C3 to C12 heteroaryl group, or any combination thereof, wherein R^{p} and R^{q} may each independently be present or be linked to each other to form a spiro structure,
x is an integer from 0 to 3,
y and z are each independently integers from 0 to 4,
w is an integer from 0 to 2, and
* is a linking point with Chemical Formula 1.

In Chemical Formula 1, Ar¹ and Ar² may each independently be a functional group represented by one of Chemical Formulas 7A to 7Q.

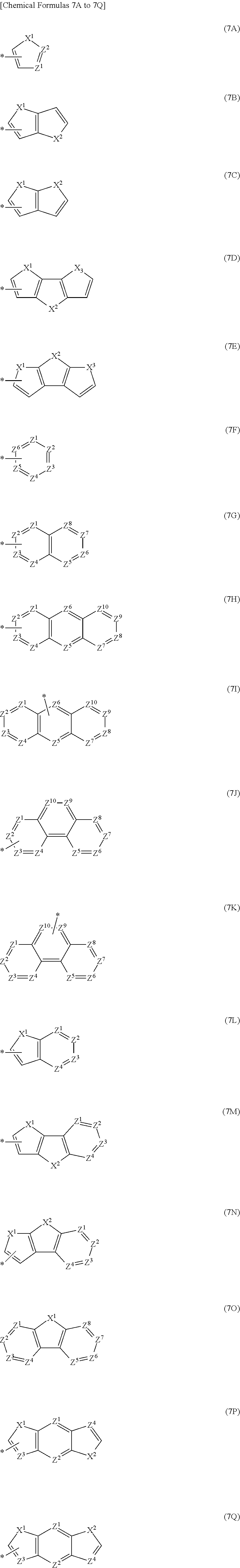

In Chemical Formulas 7A to 7Q,
X¹, X², and X³ may each independently be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z¹⁰ may each independently be CR^{x} or N (wherein R^{x} may be hydrogen, deuterium, a C1 to C10 alkyl group, a C6 to C14 aryl group, a C3 to C12 heteroaryl group, or any combination thereof), provided that when in Chemical Formula 7F, one of Z¹ to Z⁶ is a linking point with Chemical Formula 1, one of Z¹ to Z⁶ is CR^{x} wherein R^{x} is a single bond; when in Chemical Formulas 7G, 7H, and 7J, one of Z¹ to Z⁴ is a linking point with Chemical Formula 1, one of Z¹ to Z⁴ is CR^{x} wherein R^{x} is a single bond; when in Chemical Formula 71, one of Z⁵ to Z⁶ is a linking point with Chemical Formula 1, one of Z⁵ and Z⁶ is CR^{x} wherein R^{x} is a single bond; when in Chemical Formula 7K, one of Z⁹ and Z¹⁰ is a linking point with Chemical Formula 1, one of Z⁹ and Z¹⁰ is CR^{x} wherein R^{x} is a single bond; when in Chemical Formulas 7P and 7Q, Z³ is a linking point with Chemical Formula 1, Z³ is CR^{x} wherein R^{x} is a single bond,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring may be replaced by —N— (e.g., is present or is replaced by —N—), and
* is a linking point with Chemical Formula 1.

In Chemical Formula 1, Ar¹ and Ar² may each independently be a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyrimidinyl group, a substituted or unsubstituted quinolinyl group, a substituted or unsubstituted isoquinolinyl group, a substituted or unsubstituted quinoxalinyl group, a substituted or unsubstituted quinazolinyl group, a substituted or unsubstituted phenanthrolyl group, a substituted or unsubstituted pyrrolyl group, a substituted or unsubstituted thienyl group, a substituted or unsubstituted indolyl group a substituted or unsubstituted benzimidazolyl group, a substituted or unsubstituted benzthiazolyl group, or a substituted or unsubstituted carbazolyl group. Herein, “substituted” refers to replacement by a substituent selected from a halogen, a substituted or unsubstituted C6 to C20 aryl group, for example a substituted or unsubstituted C6 to C10 aryl group, a substituted or unsubstituted C6 to C20 aryloxy group, for example a substituted or unsubstituted C6 to C10 aryloxy group, a substituted or unsubstituted C3 to C20 heteroaryl group, for example a substituted or unsubstituted C3 to C10 heteroaryl group, or any combination thereof.

The compound of Chemical Formula 1 may be any one of the compounds represented by Group 1.

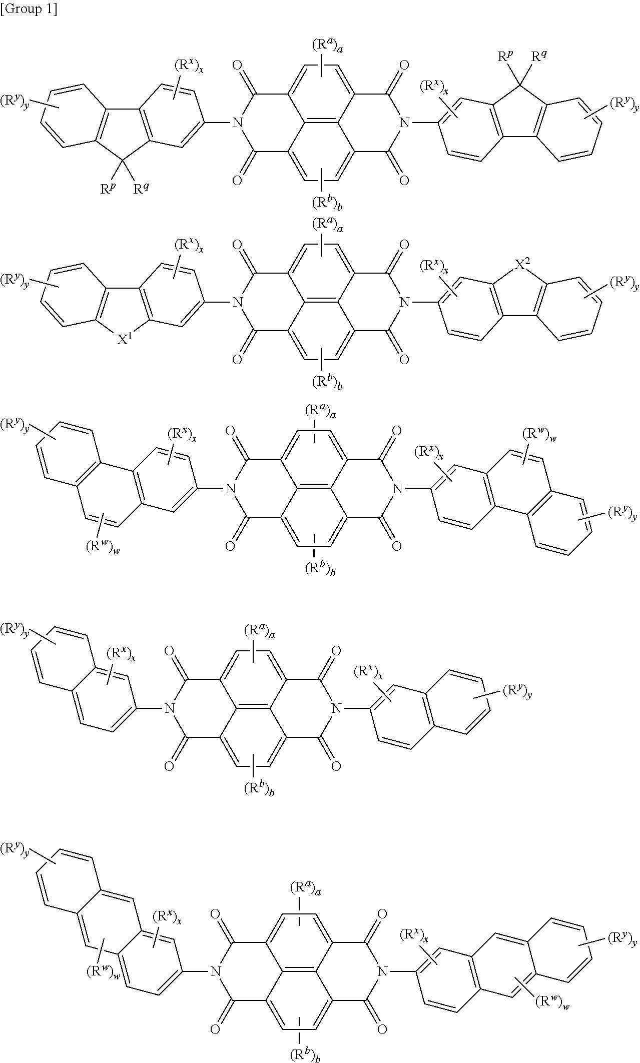

In Group 1,
R^{a}, R^{b}, a, and b are the same as R^{a}, R^{b}, a, and b, respectively, in Chemical Formula 1,
R^{x}, R^{y}, R^{w}, R^{p}, and R^{q} may each independently be hydrogen, deuterium, a C1 to C10 alkyl group, a C6 to C14 aryl group, a C3 to C12 heteroaryl group, or any combination thereof, wherein R^{p} and R^{q} may each independently be present or be linked to each other to form a spiro structure,
x is an integer from 0 to 3,
y is an integer from 0 to 4, and
w is an integer from 0 to 2.

CR^{x}, CR^{y}, and CR^{w} present in each aromatic ring in Group 1 may be replaced by N.

In Chemical Formula 2, when R¹ and R² may be an alkyl group or a cycloalkyl group, a desired level of photoelectric conversion efficiency cannot be obtained in the infrared wavelength range.

In Chemical Formula 2, R¹ and R² may be the same or different from each other.

In Chemical Formula 2, R¹ and R² may each independently be a functional group represented by one of Chemical Formulas 5A to 5L.

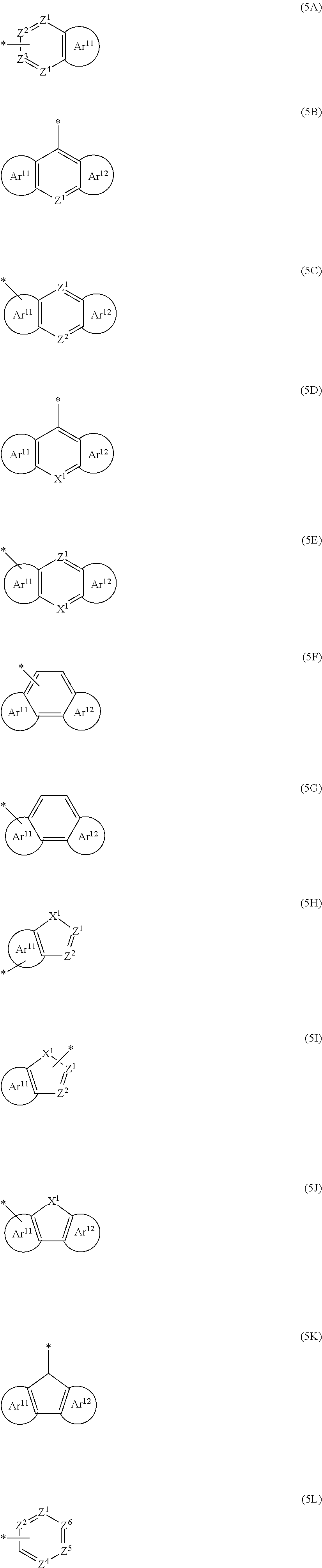

In Chemical Formulas 5A to 5L,
X¹ and X² may each independently be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z⁶ may each independently be CR^{x} or N, wherein R^{x} may be hydrogen, deuterium, a C1 to C10 alkyl group, a C6 to C14 aryl group, a C3 to C12 heteroaryl group, or any combination thereof, provided that in Chemical Formula 5A, one of Z¹ to Z⁴ is CR^{x} wherein R^{x} is a single bond, in Chemical Formula 51, one of Z¹ and Z² is CR^{x} wherein R^{x} is a single bond, and in Chemical Formula 5L, one of Z¹ to Z⁶ is CR^{x} wherein R^{x} is a single bond,
Ar¹¹ and Ar¹² may each independently be a substituted or unsubstituted C6 to C20 arene group or a substituted or unsubstituted C2 to C20 heteroarene group,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring may be present or may be replaced by —N—, and
* is a linking point with Chemical Formula 2.

In Chemical Formula 2, R¹ and R² may each independently be a functional group represented by one of Chemical Formulas 6A to 6J.

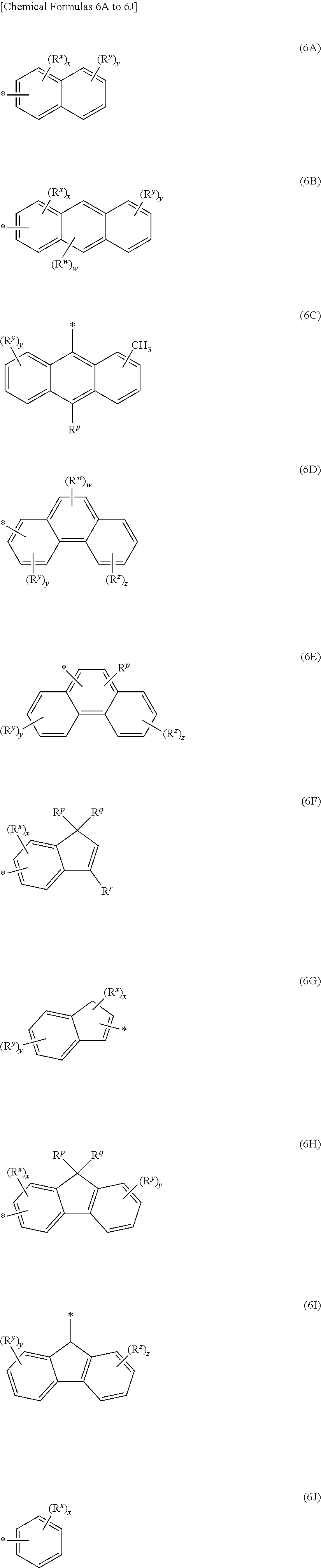

In Chemical Formulas 6A to 6J,
R^{x}, R^{y}, R^{z}, R^{w}, R^{p}, R^{q}, and R^{r} may each independently be hydrogen, deuterium, a C1 to C10 alkyl group, a C6 to C14 aryl group, a C3 to C12 heteroaryl group, or any combination thereof, wherein R^{p} and R^{q} may each independently be present or be linked to each other to form a spiro structure,
x is an integer from 0 to 3,
y and z are each independently integers from 0 to 4,
w is an integer from 0 to 2, and
* is a linking point with Chemical Formula 2.

In Chemical Formula 2, R¹ and R² may each independently be a functional group represented by one of Chemical Formulas 7A to 7Q:

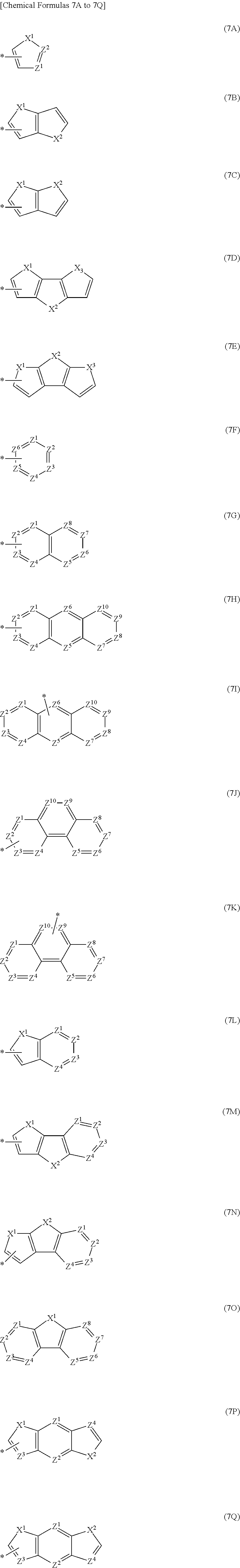

In Chemical Formulas 7A to 7Q,
X¹, X², and X³ may each independently be O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z¹⁰ may each independently be CR^{x} or N, wherein R^{x} is hydrogen, deuterium, a C1 to C10 alkyl group, a C6 to C14 aryl group, a C3 to C12 heteroaryl group, or any combination thereof, provided that when in Chemical Formula 7F, one of Z¹ to Z⁶ is a linking point with Chemical Formula 2, one of Z¹ to Z⁶ is CR^{x} wherein R^{x} is a single bond; when in Chemical Formulas 7G, 7H, 7J, and 70, one of Z¹ to Z⁴ is a linking point with Chemical Formula 2, one of Z¹ to Z⁴ is CR^{x} wherein R^{x} is a single bond; when in Chemical Formula 71, one of Z⁵ to Z⁶ is a linking point with Chemical Formula 2, one of Z⁵ and Z⁶ is CR^{x} wherein R^{x} is a single bond; when in Chemical Formula 7K, one of Z⁹ and Z¹⁰ is a linking point with Chemical Formula 2, one of Z⁹ and Z¹⁰ is CR^{x} wherein R^{x} is a single bond; when in Chemical Formulas 7P and 7Q, Z³ is a linking point with Chemical Formula 2, Z³ is CR^{x} wherein R^{x} is a single bond,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring may be present or may be replaced by —N—, and
* is a linking point with Chemical Formula 2.

The compound of Chemical Formula 2 may be any one of the compounds represented by Group 2.

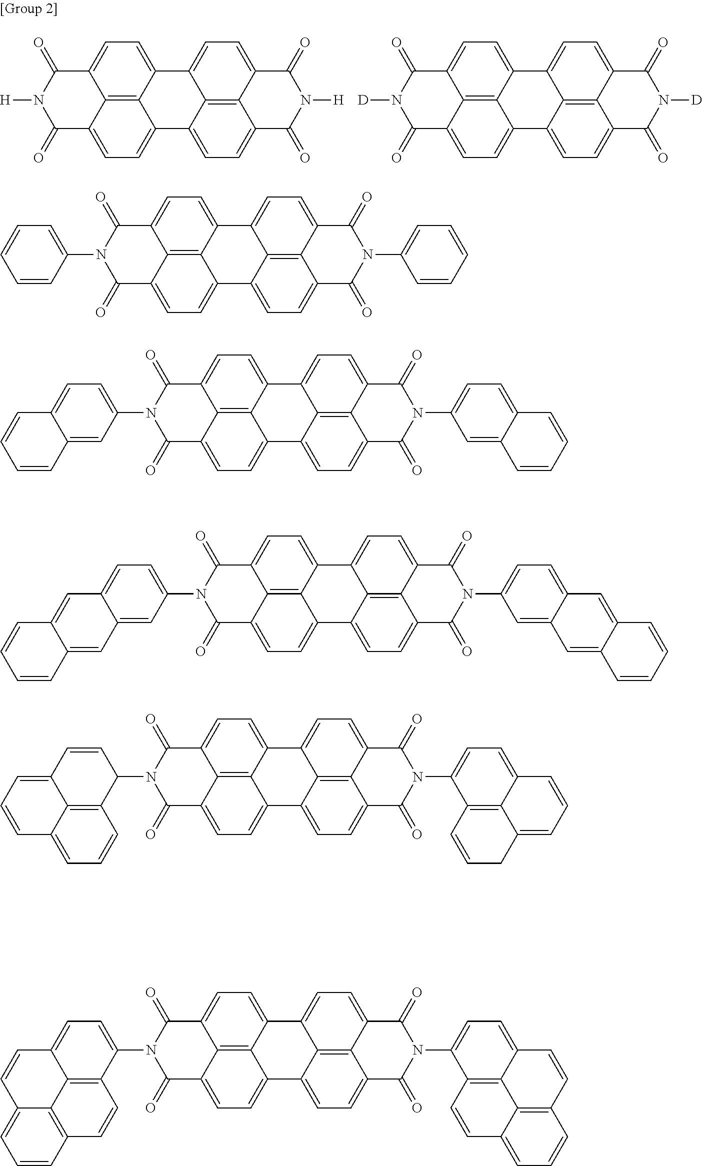

In Group 2,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof, and
at least one —CH₂— of each aromatic ring or heteroaromatic ring may be present or may be replaced by —N—.

In Chemical Formula 2, R¹ and R² may each independently be a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyrimidinyl group, a substituted or unsubstituted quinolinyl group, a substituted or unsubstituted isoquinolinyl group, a substituted or unsubstituted quinoxalinyl group, a substituted or unsubstituted quinazolinyl group, a substituted or unsubstituted phenanthrolyl group, a substituted or unsubstituted pyrrolyl group, a substituted or unsubstituted thienyl group, a substituted or unsubstituted indolyl group a substituted or unsubstituted benzimidazolyl group, a substituted or unsubstituted benzthiazolyl group, or a substituted or unsubstituted carbazolyl group.

The compound of Chemical Formula 3 may be one of the compounds represented by Group 3 (any one of Chemical Formulas 3-1 to 3-9).

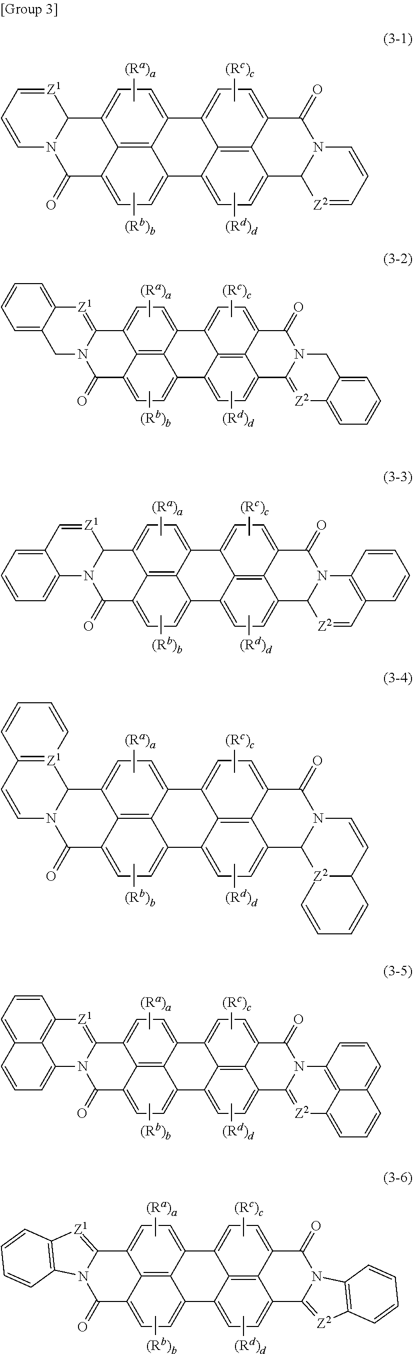

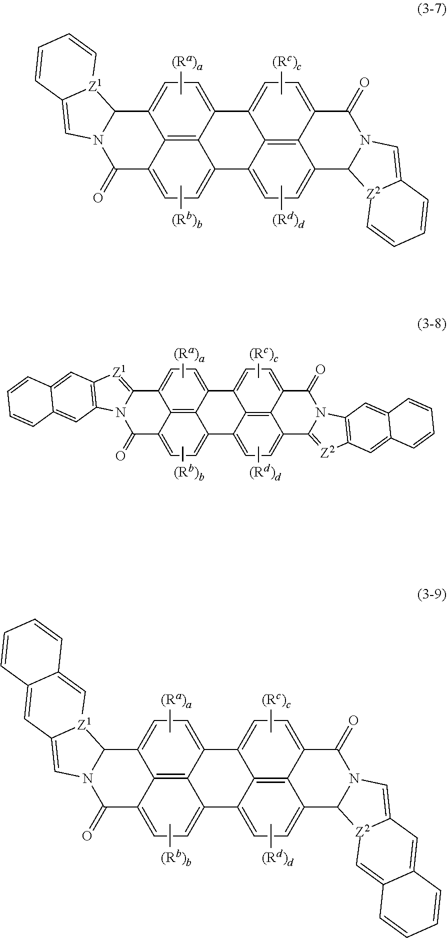

In Group 3 (Chemical Formulas 3-1 to 3-9),
R^{a}, R^{b}, R^{c}, R^{d}, a, b, c, and d are the same as R^{a}, R^{b}, R^{c}, R^{d}, a, b, c, and d, respectively, in Chemical Formula 3,
Z¹ and Z² are each independently CR^{x} or N, wherein R^{x} is hydrogen, deuterium, A C1 to C10 alkyl group, a C6 to C14 aryl group, a C3 to C12 heteroaryl group, or any combination thereof,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof, and
at least one —CH₂— of each aromatic ring or heteroaromatic ring may be present or may be replaced by —N—.

The compounds of Group 3 may include, for example, compounds of Group 3-1.

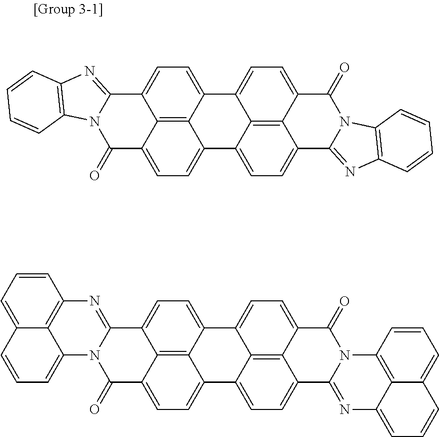 [SMILES: O=c1c2ccc3c4ccc5c6c(ccc(c7ccc(c2c37)c2nc3ccccc3n12)c46)c(=O)n1c2ccccc2nc51 ; O=c1c2ccc3c4ccc5c6c(ccc(c7ccc(c2c37)c2nc3cccc7cccc(c73)n12)c46)c(=O)n1c2cccc3cccc(nc51)c32]

The compound of Chemical Formula 4 may be a compound represented by one of the compounds represented by Group 4 (any one of Chemical Formulas 4-1 to 4-9).

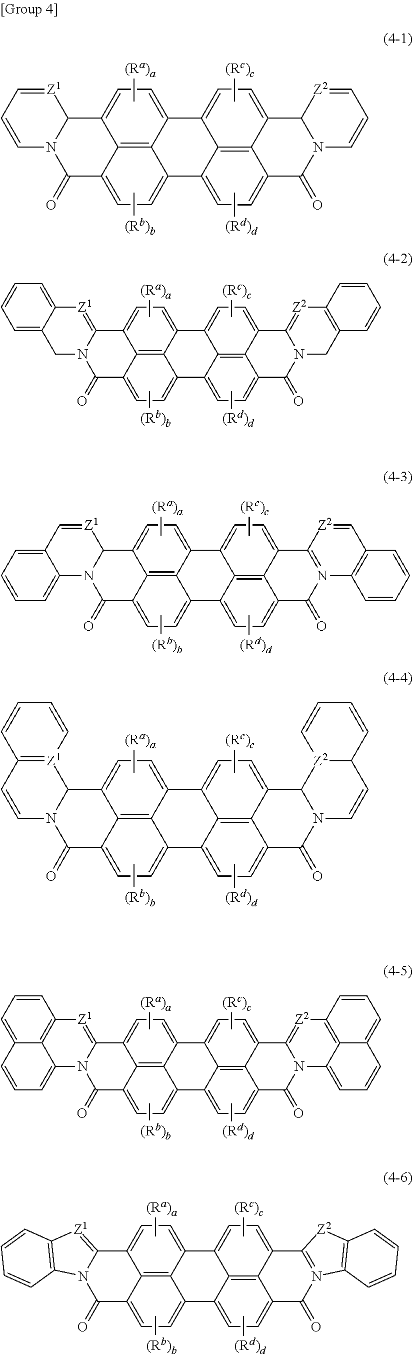

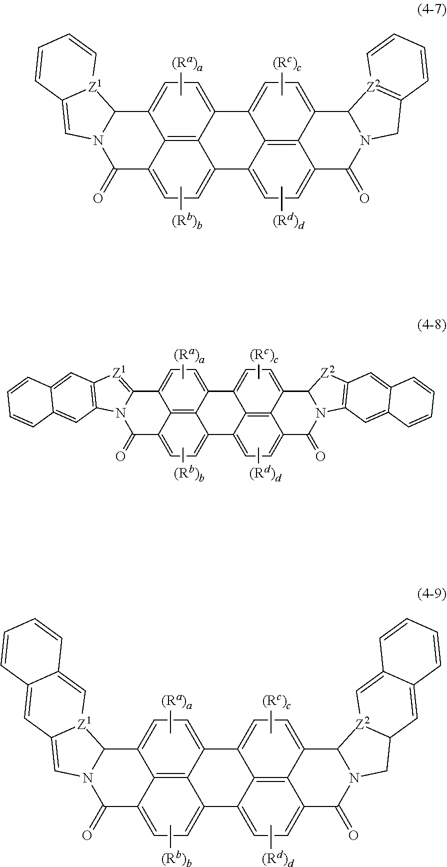

In Group 4 (Chemical Formulas 4-1 to 4-9),
R^{a}, R^{b}, R^{c}, R^{d}, a, b, c, and d are the same as R^{a}, R^{b}, R^{c}, R^{d}, a, b, c, and d, respectively, in Chemical Formula 4,
Z¹ and Z² are each independently CR^{x} or N, wherein R^{x} is hydrogen, deuterium, A C1 to C10 alkyl group, a C6 to C14 aryl group, a C3 to C12 heteroaryl group, or any combination thereof,
at least one hydrogen of each aromatic ring or heteroaromatic ring may be present or may be replaced by deuterium, a C1 to C10 alkyl group, a C1 to C10 alkoxy group, a C6 to C10 aryl group, a C6 to C10 aryloxy group, or any combination thereof, and
at least one —CH₂— of each aromatic ring or heteroaromatic ring may be present or may be replaced by —N—.

For example, a HOMO energy level of the compounds of Chemical Formulas 1 to 4 may be about 5.0 eV to about 6.5 eV (based on absolute value), and within this range, greater than or equal to about 5.1 eV, greater than or equal to about 5.2 eV, and less than or equal to about 6.49 eV, less than or equal to about 6.48 eV, or less than or equal to about 6.47 eV.

For example, the LUMO energy level of the compounds of Chemical Formulas 1 to 4 may be about 3.4 eV to about 4.5 eV (based on absolute value), and within the above range, greater than or equal to about 3.41 eV, greater than or equal to about 3.42 eV, greater than or equal to about 3.43 eV, greater than or equal to about 3.44 eV, greater than or equal to about 3.45 eV, greater than or equal to about 3.46 eV, or greater than or equal to about 3.47 eV and less than or equal to about 4.49 eV, less than or equal to about 4.48 eV, less than or equal to about 4.47 eV, less than or equal to about 4.46 eV, less than or equal to about 4.45 eV, less than or equal to about 4.44 eV, less than or equal to about 4.43 eV, or less than or about 4.42 eV.

The compound represented by one of Chemical Formulas 1 to 4 may be a material that may be vacuum-deposited, and may be, for example, a sublimable material that may be vacuum-deposited by sublimation without decomposition or polymerization in a particular (or, alternatively, predetermined) temperature range. The sublimable material may be identified by thermogravimetric analysis (TGA). The organic compound may be an organic material that may lose a weight with increasing temperature and for example may lose a weight by at least about 50% of an initial weight thereof, without substantial decomposition or polymerization.

In addition, a micro lens array (MLA) may be formed to concentrate light after manufacturing an organic photoelectric device (also referred to herein as simply a photoelectric device) during manufacture of an image sensor. This micro lens array may require a relatively high temperature (greater than or equal to about 150° C., greater than or equal to about 160° C., for example greater than or equal to about 170° C., or greater than or equal to about 180° C.). The performance of the photoelectric devices (e.g., organic photoelectric devices) may be required not to be deteriorated in these heat-treatment processes. The performance deterioration of the organic photoelectric device during the heat treatment of MLA may be caused not by chemical decomposition of an organic material but its morphology change. The morphology change is in general caused, when a material starts a thermal vibration due to a heat treatment, but a material having a firm molecule structure may not have the thermal vibration and be limited and/or prevented from the deterioration by the heat treatment. The compounds of Chemical Formulas 1 to 4 may be maintained stably even in the MLA heat treatment process by appropriately controlling the conjugate length of the molecules to suppress vibrations caused by heat of the molecules, thereby ensuring process stability and furthermore reducing the likelihood of process defects in a photoelectric device including an electron auxiliary layer and/or reducing, minimizing, or preventing performance deterioration of the photoelectric device, and thus improving operational reliability thereof, based on the electron auxiliary layer including any one compound selected from compounds represented by Chemical Formulas 1 to 4 and any combination thereof.

The photoelectric device 100 may include the electron auxiliary layer 150 as a first electron auxiliary layer, and may further include an additional second electron auxiliary layer between the second electrode 120 and the first electron auxiliary layer 150 and/or between the first electron auxiliary layer 150 and the active layer 130. The second electron auxiliary layer may be an electron injection layer, an electron transport layer, and/or a hole blocking layer.

The electron injection layer, the electron transport layer, and/or the hole blocking layer may include, for example, a metal halide such as LiF, NaCl, CsF, RbCl and Rbl; a lanthanide metal such as Yb; a metal such as calcium (Ca), potassium (K), aluminum (Al), or an alloy thereof; a metal oxide such as Li₂O or BaO; Liq (lithium quinolate), Alq3 (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tri(1-phenyl-1H-benzo[d]imidazol-2-yl)phenyl), BCP (2,9-dimethyl-4,7-diphenyl-1,10-phenanthroline), Bphen (4,7-diphenyl-1,10-phenanthroline), TAZ (3-(4-Biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-Biphenyl-4-olato)aluminum), Bebq₂ (beryllium bis(benzoquinolin-10-olate), ADN (9,10-di(naphthalene-2-yl)anthracene), BmPyPhB (1,3-bis[3,5-di(pyridin-3-yl)phenyl]benzene), or any combination thereof, but are not limited thereto.

A thickness of the electron auxiliary layer 150 may be about 2 nm to about 200 nm, within the above range, greater than or equal to about 3 nm, greater than or equal to about 4 nm, greater than or equal to about 5 nm, or greater than or equal to about 6 nm and less than or equal to about 150 nm, less than or equal to about 140 nm, less than or equal to about 130 nm, less than or equal to about 120 nm, less than or equal to about 110 nm, less than or equal to about 100 nm, less than or equal to about 90 nm, less than or equal to about 80 nm, less than or equal to about 70 nm, less than or equal to about 60 nm, less than or equal to about 50 nm, less than or equal to about 40 nm, or less than or equal to about 30 nm.

The photoelectric device 100 may include a hole auxiliary layer 140 between the first electrode 110 and the active layer 130. The hole auxiliary layer 140 may be a hole injection layer, a hole transport layer, and/or an electron blocking layer.

The hole injection layer, the hole transport layer, and/or the electron blocking layer may include, for example, a phthalocyanine compound such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′,4″-tris(N,N-diphenylamino)triphenylamine), 2-TNATA (4,4′,4″-tris{N,-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/Camphor sulfonic acid), PANI/PSS (polyaniline/poly(4-styrenesulfonate)), NPB (N,N′-di(naphthalene-1-yl)-N,N′-diphenylbenzidine), polyetherketone including triphenylamine (TPAPEK), 4-isopropyl-4′-methyldiphenyliodonium[tetrakis(pentafluorophenyl)borate], HAT-CN (dipyrazino[2,3-f: 2′,3′-h] quinoxaline-2,3,6,7,10,11-hexacarbonitrile), a carbazole-based derivative such as N-phenylcarbazole, polyvinylcarbazole, and the like, a fluorene-based derivative, TPD (N,N′-bis(3-methylphenyl)-N,N′-diphenyl-[1,1-biphenyl]-4,4′-diamine), a triphenylamine-based derivative such as TCTA (4,4′,4″-tris(N-carbazolyl)triphenylamine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), or any combination thereof, but is not limited thereto.

The photoelectric device 100 may further include an anti-reflection layer (not shown) disposed on the lower portion of the first electrode 110 or on the upper portion of the second electrode 120. For example, when the first electrode 110 is a light-receiving electrode, the anti-reflection layer may be disposed on the lower portion of the first electrode 110. For example, when the second electrode 120 is a light-receiving electrode, the anti-reflection layer may be disposed on the upper portion of the second electrode 120. The anti-reflection layer is disposed at a light incidence side and lowers reflectance of light of incident light and thereby light absorbance is further improved. The anti-reflection layer may include, for example a material having a refractive index of about 1.6 to about 2.5, and may include for example at least one of metal oxide, metal sulfide, or an organic material having a refractive index within the above ranges. The anti-reflection layer may include, for example a metal oxide such as aluminum-containing oxide, molybdenum-containing oxide, tungsten-containing oxide, vanadium-containing oxide, rhenium-containing oxide, niobium-containing oxide, tantalum-containing oxide, titanium-containing oxide, nickel-containing oxide, copper-containing oxide, cobalt-containing oxide, manganese-containing oxide, chromium-containing oxide, tellurium-containing oxide, or any combination thereof; a metal sulfide such as zinc sulfide; or an organic material such as an amine derivative, but is not limited thereto.

The photoelectric device 100 may further include a focusing lens (not shown). The focusing lens may collect the light to a single point by controlling the direction of the incident light at a light incident position. The focusing lens may have a shape of, for example, a cylinder or a hemisphere, but is not limited thereto.

In the photoelectric device 100, when light (e.g., incident light) enters from the first electrode 110 or the second electrode 120 and the active layer 130 absorbs the light in a particular (or, alternatively, predetermined) wavelength region, excitons may be generated thereinside (e.g., in the active layer 130).

The excitons may be separated into holes and electrons in the active layer 130, and the separated holes may be transported to an anode that is one of the first electrode 110 or the second electrode 120 and the separated electrons may be transported to the cathode that is the other of the first electrode 110 or the second electrode 120 so as to flow a current (e.g., to induce a flow of an electrical current).

The photoelectric device 100 may be applied to various fields using light in an infrared wavelength region as an electrical signal, and may be applied to, for example, a sensor. The sensor including the photoelectric device 100 may be, for example, an image sensor for improving sensitivity in a low-light environment, a sensor for increasing detection capability of 3D images by broadening the dynamic range for detailed black and white contrast, a security sensor, a vehicle sensor, a biometric sensor, or the like. The biometric sensor may be, for example, an iris sensor, a distance sensor, a fingerprint sensor, or a blood vessel distribution sensor, but is not limited thereto. The sensor including the photoelectric device 100 may be, for example, a CMOS infrared sensor or a CMOS image sensor.

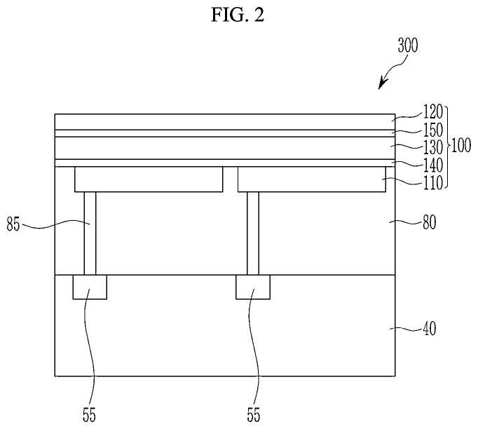

FIG. 2 is a cross-sectional view showing an example of a sensor according to some example embodiments.

The sensor 300 according to some example embodiments includes a semiconductor substrate 40, an insulation layer 80, and a photoelectric device 100.

The semiconductor substrate 40 may be a silicon substrate and is integrated with a transmission transistor (not shown) and a charge storage 55. The charge storage 55 may be integrated in each pixel. The charge storage 55 is electrically connected to the photoelectric device 100 and information of the charge storage 55 may be transmitted by the transmission transistor. The semiconductor substrate 40 may not include a separate integrated photodiode such as a silicon photodiode (e.g., the semiconductor substrate 40 may not include any separate integrated photodiodes therein).

A metal wire (not shown) and a pad (not shown) are formed on the semiconductor substrate 40. In order to decrease signal delay, the metal wire and pad may be made of a metal having low resistivity, for example, aluminum (Al), copper (Cu), silver (Ag), and alloys thereof, but is not limited thereto. However, it is not limited to the structure and the metal wire and pads may be disposed under the semiconductor substrate 40.

The insulation layer 80 is formed on the metal wire and the pad. The insulation layer 80 may be made of an inorganic insulating material such as a silicon oxide and/or a silicon nitride, or a low dielectric constant (low K) material such as SiC, SiCOH, SiCO, and/or SiOF. The insulation layer 80 has a trench 85 exposing the charge storage 55. The trench 85 may be filled with fillers.

The aforementioned photoelectric device 100 is formed on the insulation layer 80. As described above, the photoelectric device 100 may include a first electrode 110, a second electrode 120, an active layer 130, and an electron auxiliary layer 150 and may further include a hole auxiliary layer 140. The description of the photoelectric device 100 is the same as described above. The photoelectric devices 100 may be arranged along rows and/or columns on the semiconductor substrate 40, for example, in a matrix form.

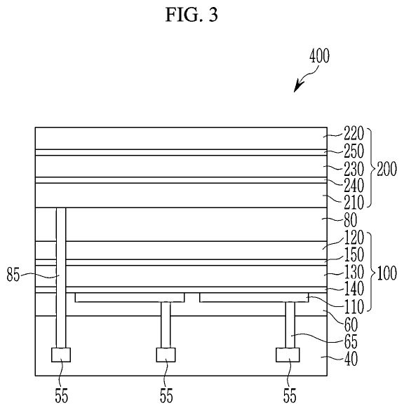

FIG. 3 is a cross-sectional view showing a sensor according to some example embodiments.

The sensor according to some example embodiments may include a plurality of sensors having different functions, and the plurality of sensors having different functions may be stacked along the thickness direction of the semiconductor substrate 40.

As an example, the plurality of sensors having different functions may be an infrared sensor and/or an image sensor. For example, a sensor for improving the sensitivity of the image sensor in a low-light environment, a sensor to increase the detection ability of a three-dimensional image by expanding the dynamic range that distinguishes between black and white details, a security sensor, a vehicle sensor, a biometric sensor, and an image sensor may be independently selected and combined. The image sensor may absorb and detect light in a red wavelength region, a green wavelength region, a blue wavelength region, or any combination thereof.

For example, the plurality of sensors may include two infrared photodiodes. For example, a plurality of infrared photodiodes may include a first infrared photodiode absorbing light of a first infrared wavelength spectrum belonging to an infrared wavelength region and photoelectrically converting it and a second infrared photodiode absorbing light of a second infrared wavelength spectrum belonging to the infrared wavelength region and photoelectrically converting it.

A peak wavelength of the first infrared wavelength spectrum and a peak wavelength of the second infrared wavelength spectrum may be different from each other, for example, within a wavelength region of greater than about 1000 nm and less than or equal to 3000 nm, for example, a peak wavelength difference of the first infrared wavelength spectrum and the second infrared wavelength spectrum may be greater than or equal to about 30 nm and within the above range, greater than or equal to about 50 nm, greater than or equal to about 70 nm, greater than or equal to about 80 nm, or greater than or equal to about 90 nm and may be less than or equal to about 3000 nm.

For example, either one of the peak wavelength of the first infrared wavelength spectrum or the peak wavelength of the second infrared wavelength spectrum may belong to greater than or equal to about 1000 nm and less than 1200 nm, and the other one of the peak wavelength of the first infrared wavelength spectrum or the peak wavelength of the second infrared wavelength spectrum may belong to about 1200 nm to about 3000 nm.

For example, a plurality of sensors may include one infrared sensor and one image sensor. For example, the plurality of sensors may have a stacked structure of the above infrared sensor and an image sensor detecting light of a red wavelength region, a green wavelength region, a blue wavelength region, or any combination thereof.

Referring to FIG. 3, the sensor 400 according to some example embodiments includes the upper photodiode 200, the insulation layer 80, the photoelectric device 100, and the semiconductor substrate 40. The upper photodiode 200 and the photoelectric device 100 are stacked.

The upper photodiode 200 may be another infrared photodiode (infrared sensor) differing from the photoelectric device 100 or a visible photodiode (an image sensor) detecting light in a visible wavelength region.

The upper photodiode 200 may be a photoelectric conversion device and include a lower electrode 210, an upper electrode 220, an active layer 230, and auxiliary layers 240 and 250. Either one of the lower electrode 210 or the upper electrode 220 may be an anode, while the other one may be a cathode. The active layer 230 may absorb at least a portion of light of the infrared wavelength region or the visible wavelength region and photoelectrically convert it (the absorbed light). The light in the visible wavelength region may be light of a red wavelength region, a green wavelength region, a blue wavelength region, or any combination thereof. The infrared wavelength region absorbed in the active layer 230 of the upper photodiode 200 may not be overlapped with the infrared wavelength region detected in the photoelectric device 100. The auxiliary layers 240 and 250 may each be a hole injection layer (HIL), a hole transport layer (HTL), an electron blocking layer, an electron injection layer (EIL), an electron transport layer (ETL), a hole blocking layer, an optical auxiliary layer, or any combination thereof.

The photoelectric device 100 is the same as described above.

Between the upper photodiode 200 and the photoelectric device 100, an insulation layer 80 may be formed. The insulation layer 80 has a trench 85 exposing a charge storage 55, and the trench 85 may be filled with a filler.

The semiconductor substrate 40 may be the same as described above, and the charge storage 55 is electrically connected to the first electrode 110 of the photoelectric device 100 or the lower electrode 210 of the upper photodiode 200.

Between the photoelectric device 100 and the semiconductor substrate 40, an insulation layer 60 may be formed. The insulation layer 60 has a trench 65 exposing the charge storage 55, and the trench 65 may be filled with a filler. The insulation layer 60 may be made of an inorganic insulating material such as a silicon oxide and/or a silicon nitride, or a low dielectric constant (low K) material such as SiC, SiCOH, SiCO, and/or SiOF. The insulation layer 60 may comprise a same material as the insulation layer 80.

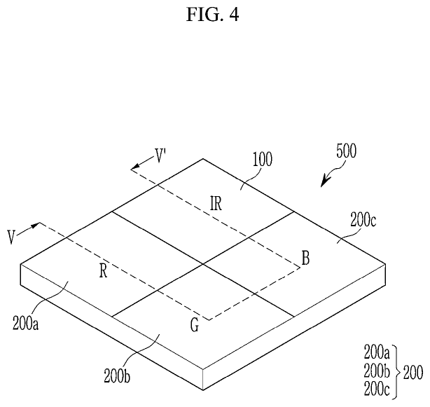

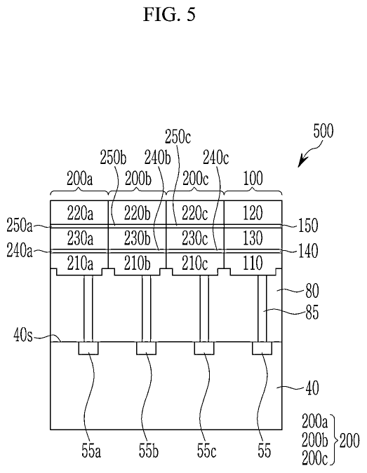

FIG. 4 is a schematic perspective view of a sensor according to some example embodiments, and FIG. 5 is a schematic cross-sectional view of the sensor of FIG. 4 along view line V-V′ in FIG. 4.

Referring to FIGS. 4 and 5, the sensor 500 according to some example embodiments includes the semiconductor substrate 40, the photoelectric device 100, and the visible photodiode 200. The visible photodiode 200 includes a red photodiode 200a configured to sense light in a red wavelength region, a green photodiode 200b configured to sense light in a green wavelength region, and a blue photodiode 200c configured to sense light in a blue wavelength region.

The aforementioned photoelectric device 100, the red photodiode 200a, green photodiode 200b, and the blue photodiode 200c are aligned in a parallel direction to the surface 40s of the semiconductor substrate 40 and respectively electrically connected to charge storage 55 integrated in the semiconductor substrate 40. The red photodiode 200a, the green photodiode 200b, and the blue photodiode 200c may each be a photoelectric conversion device.

The red photodiode 200a includes a lower electrode 210a, a red photoelectric conversion layer 230a, an upper electrode 220a, and auxiliary layers 240a and 250a. The green photodiode 200b includes a lower electrode 210b, a green photoelectric conversion layer 230b, an upper electrode 220b, and auxiliary layers 240b and 250b. The blue photodiode 200c includes a lower electrode 210c, a blue photoelectric conversion layer 230c, an upper electrode 220c, and auxiliary layers 240c and 250c. The red photoelectric conversion layer 230a may selectively absorb light in a red wavelength region for photoelectric conversion, the green photoelectric conversion layer 230b may selectively absorb light in a green wavelength region for photoelectric conversion, and the blue photoelectric conversion layer 230c may selectively absorb light in a blue wavelength region to perform photoelectric conversion. The lower electrodes 210a, 210b, and 210c and the upper electrodes 220a, 220b, and 220c may be light-transmitting electrodes, respectively. The lower electrodes 210a, 210b, and 210c may comprise a same material as the first electrode 110 as described herein. The upper electrodes 220a, 220b, and 220c may comprise a same material as the second electrode 120 as described herein. The red photoelectric conversion layer 230a, the green photoelectric conversion layer 230b, and the blue photoelectric conversion layer 230c may each independently include an inorganic light absorbing material, an organic light absorbing material, an organic-inorganic light absorbing material, or any combination thereof. For example, at least one of the red photoelectric conversion layer 230a, the green photoelectric conversion layer 230b, or the blue photoelectric conversion layer 230c may include an organic photoelectric conversion material. The auxiliary layers 240a, 240b, and 240c may comprise a same material as the hole auxiliary layer 140 as described herein. The auxiliary layers 250a, 250b, and 250c may comprise a same material as the electron auxiliary layer 150 as described herein.

The organic photoelectric conversion material may include a p-type semiconductor and an n-type semiconductor. The p-type semiconductor may be one or more compounds as described in U.S. Patent Publication No. US-2016-0149132-A1 and/or U.S. Patent Publication No. US-2021-0234103-A1, the description(s) of such compound(s) therein incorporated by reference herein, and the n-type semiconductor may include fullerene or fullerene derivatives.

At least one of the auxiliary layers 240a, 240b, 240c, 250a, 250b, or 250c may be omitted.

The photoelectric device 100, the red photodiode 200a, the green photodiode 200b, and the blue photodiode 200c are electrically connected to the charge storages 55, 55a, 55b, and 55c respectively integrated on the semiconductor substrate 40.

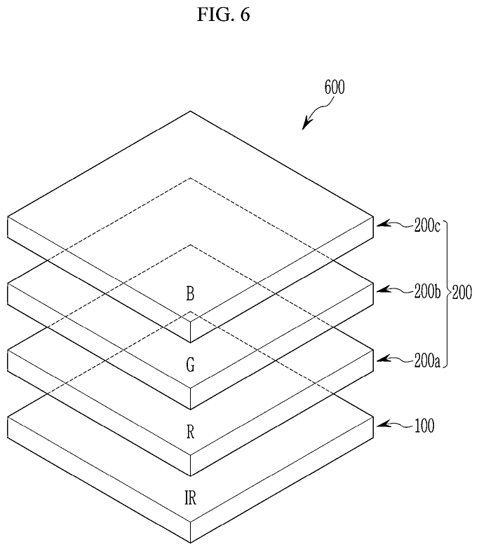

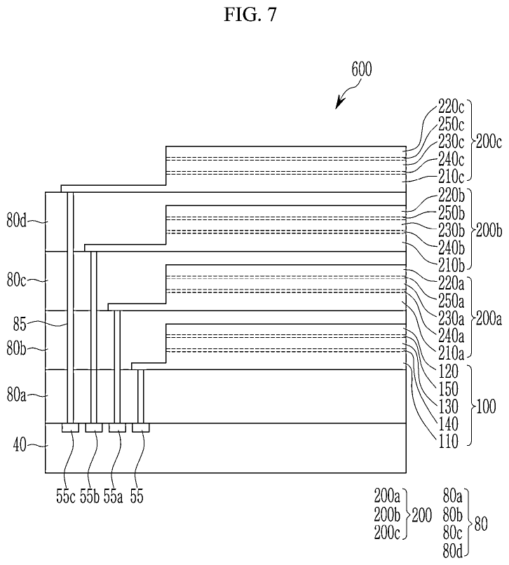

FIG. 6 is a schematic perspective view of a sensor according to some example embodiments, and FIG. 7 is a schematic cross-sectional view of the sensor of FIG. 6.

Referring to FIGS. 6 and 7, the sensor 600 according to some example embodiments includes a semiconductor substrate 40, a photoelectric device 100, a visible photodiode 200, and an insulation layer 80.

The visible photodiode 200 may be an image sensor absorbing at least a portion of light in a visible wavelength region and converting it into electrical signals, a red photodiode 200a detecting light (e.g., configured to detect light) in a red wavelength region, green photodiode 200b detecting light in a green wavelength region, and a blue photodiode 200c detecting light in a blue wavelength region.

The photoelectric device 100 and the visible photodiode 200 may be stacked along a thickness direction of the semiconductor substrate 40. For example, the photoelectric device 100 is disposed at the bottom, while the visible photodiode 200 is disposed on top, but the present inventive concepts are not limited thereto. In the drawing, the red photodiode 200a, the green photodiode 200b, and the blue photodiode 200c are sequentially stacked, but the red photodiode 200a, the green photodiode 200b, and the blue photodiode 200c may be stacked in various orders.

The photoelectric device 100, the red photodiode 200a, the green photodiode 200b, and the blue photodiode 200c are the same as described above.

The photoelectric device 100, the red photodiode 200a, green photodiode 200b and blue photodiode 200c are each electrically connected to charge storages 55, 55a, 55b, and 55c. Between the semiconductor substrate 40 and the photoelectric device 100 and between photoelectric device 100 and the visible photodiode 200, each insulation layer 80a, 80b, 80c, and 80d is disposed. The insulation layers 80a, 80b, 80c, and 80d may each be made of a same or different materials, including for example an inorganic insulating material such as a silicon oxide and/or a silicon nitride, or a low dielectric constant (low K) material such as SiC, SiCOH, SiCO, and/or SiOF.

The aforementioned photoelectric device 100 and/or sensors 300, 400, 500, and 600 may be applied to various electronic devices, for example, a mobile phone, a digital camera, a display device, a biometric device, a security device, an automobile electronic component, and/or like but is not limited thereto.

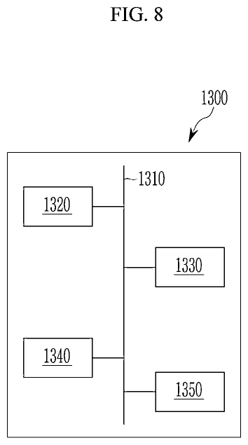

FIG. 8 is a schematic view illustrating an example of the configuration of an electronic device according to some example embodiments.

Referring to FIG. 8, the electronic device 1300 includes a processor 1320, a memory 1330, a sensor 1340, and a display unit 1350 which are electrically connected through a bus 1310. The display unit 1350 may include a display panel, touchscreen display panel, or the like, for example a light emitting diode (LED) display panel, an organic LED (OLED) display panel, or the like. The sensor 1340 may be the aforementioned sensor 300, 400, 500, or 600.

The processor 1320 may include one or more articles of processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 1320 may control, for example, a display operation of the sensor 1340 or a sensor operation of the photoelectric device.

The memory 1330 may be a non-transitory computer readable storage medium, such as, for example, as a solid-state drive (SSD) and may store an instruction program (e.g., program of instructions), and the processor 1320 may perform a function related to the sensor 1340 by executing the stored instruction program.

The processor 1320 may additionally execute the stored program and display it as an image (e.g., execute the program to display one or more images) on the display unit 1350.

The units and/or modules described herein may be implemented using hardware constituent elements and software constituent elements. The units and/or modules described herein may include, may be included in, and/or may be implemented by one or more articles of processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

The method according to the foregoing example embodiments may be recorded in a non-transitory computer readable storage device including program instructions for implementing various operations of some example embodiments. The storage device may also include program instructions, data files, data structures, and the like alone or in combination. The program instructions recorded in the storage device may be specially designed for some example embodiments or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of some example embodiments.

Hereinafter, some example embodiments are illustrated in more detail with reference to examples. However, the scope of the inventive concepts is not limited to these examples.

### Manufacture of Photoelectric Device I

### Example 1-1

ITO (10 nm), Ag (120 nm), and ITO (10 nm) are sequentially deposited on a glass substrate to form a first electrode having an ITO/Ag/ITO structure. A 25 nm-thick hole auxiliary layer is formed by depositing a compound represented by Chemical Formula A-1. Subsequently, on the hole auxiliary layer, tin naphthalocyanine dichloride (Sn-naphthalocyanine dichloride) (p-type semiconductor) and C60 (n-type semiconductor) represented by Chemical Formula B-1 are co-deposited to have a thickness ratio (volume ratio) of 1:5 to form a 210 nm-thick photoelectric conversion layer (active layer). Then, a compound represented by Chemical Formula 1-1 is deposited on the photoelectric conversion layer to form a 4 nm-thick electron auxiliary layer, and silver (Ag) is deposited on the photoelectric conversion layer to form a 30 nm-thick second electrode, manufacturing a photoelectric device.

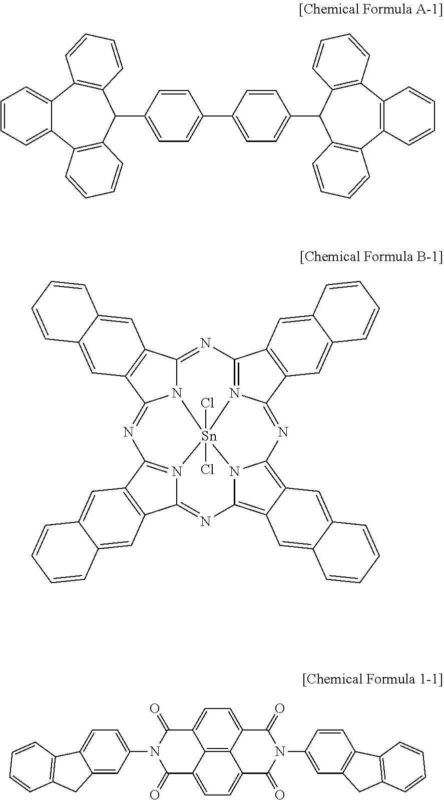

### Example 1-2

ITO (10 nm), Ag (120 nm), and ITO (10 nm) are sequentially deposited on a glass substrate to form a first electrode having an ITO/Ag/ITO structure. A 30 nm-thick hole auxiliary layer is formed by depositing a compound represented by Chemical Formula A-1. Subsequently, on the hole auxiliary layer, tin naphthalocyanine dichloride (Sn-naphthalocyanine dichloride) (p-type semiconductor) and C60 (n-type semiconductor) represented by Chemical Formula B-1 are co-deposited to have a thickness ratio (volume ratio) of 1:5.67 to form a 200 nm-thick photoelectric conversion layer (active layer). Then, a compound represented by Chemical Formula 1-1 is deposited on the photoelectric conversion layer to form a 13 nm-thick electron auxiliary layer, and silver (Ag) is deposited on the photoelectric conversion layer to form a 30 nm-thick second electrode, manufacturing a photoelectric device.

### Example 1-3

ITO (10 nm), Ag (120 nm), and ITO (10 nm) are sequentially deposited on a glass substrate to form a first electrode having an ITO/Ag/ITO structure. A 30 nm-thick hole auxiliary layer is formed by depositing a compound represented by Chemical Formula A-1. Subsequently, on the hole auxiliary layer, tin naphthalocyanine dichloride (Sn-naphthalocyanine dichloride) (p-type semiconductor) and C60 (n-type semiconductor) represented by Chemical Formula B-1 are co-deposited to have a thickness ratio (volume ratio) of 1:4.86 to form a 205 nm-thick photoelectric conversion layer (active layer). Then, a compound represented by Chemical Formula 1-1 is deposited on the photoelectric conversion layer to form a 5 nm-thick electron auxiliary layer, and silver (Ag) is deposited on the photoelectric conversion layer to form a 30 nm-thick second electrode, manufacturing a photoelectric device.

### Example 1-4

ITO (10 nm), Ag (120 nm), and ITO (10 nm) are sequentially deposited on a glass substrate to form a first electrode having an ITO/Ag/ITO structure. A 30 nm-thick hole auxiliary layer is formed by depositing a compound represented by Chemical Formula A-1. Subsequently, on the hole auxiliary layer, tin naphthalocyanine dichloride (Sn-naphthalocyanine dichloride) (p-type semiconductor) and C60 (n-type semiconductor) represented by Chemical Formula B-1 are co-deposited to have a thickness ratio (volume ratio) of 1:4.57 to form a 195 nm-thick photoelectric conversion layer (active layer). Then, a compound represented by Chemical Formula 1-1 is deposited on the photoelectric conversion layer to form a 5 nm-thick electron auxiliary layer, and silver (Ag) is deposited on the photoelectric conversion layer to form a 30 nm-thick second electrode, manufacturing a photoelectric device.

### Example 1-5

ITO (10 nm), Ag (120 nm), and ITO (20 nm) are sequentially deposited on a glass substrate to form a first electrode having an ITO/Ag/ITO structure. A 30 nm-thick hole auxiliary layer is formed by depositing a compound represented by Chemical Formula A-1. Subsequently, on the hole auxiliary layer, tin naphthalocyanine dichloride (Sn-naphthalocyanine dichloride) (p-type semiconductor) and C60 (n-type semiconductor) represented by Chemical Formula B-1 are co-deposited to have a thickness ratio (volume ratio) of 1:4.74 to form a 218 nm-thick photoelectric conversion layer (active layer). Then, a compound represented by Chemical Formula 1-1 is deposited on the photoelectric conversion layer to form a 3 nm-thick electron auxiliary layer, and silver (Ag) is deposited on the photoelectric conversion layer to form a 30 nm-thick second electrode, manufacturing a photoelectric device.

### Example 2-1

A photoelectric device is manufactured in the same manner as Example 1-1, except that the compound represented by Chemical Formula 2-1 is used instead of the compound represented by Chemical Formula 1-1.

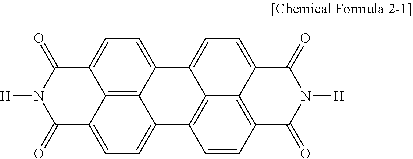 [SMILES: O=C1NC(=O)c2ccc3c4ccc5c6c(ccc(c7ccc1c2c73)c64)C(=O)NC5=O]

A photoelectric device is manufactured in the same manner as Example 1-1, except that the compound represented by Chemical Formula 2-2 is used instead of the compound represented by Chemical Formula 1-1.

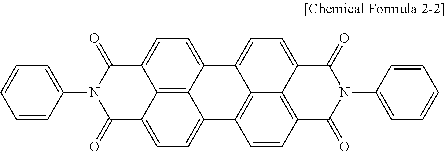 [SMILES: O=C1c2ccc3c4ccc5c6c(ccc(c7ccc(c2c37)C(=O)N1c1ccccc1)c64)C(=O)N(c1ccccc1)C5=O]

### Example 3-1

A photoelectric device is manufactured in the same manner as Example 1-1, except that the compound represented by Chemical Formula 3-1 is used instead of the compound represented by Chemical Formula 1-1.

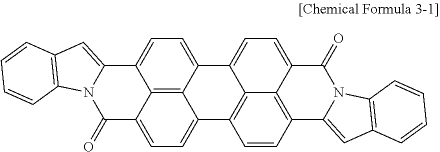 [SMILES: O=c1c2ccc3c4ccc5c6c(ccc(c7ccc(c2c37)c2cc3ccccc3n12)c46)c(=O)n1c2ccccc2cc51]

### Example 3-2

A photoelectric device is manufactured in the same manner as Example 1-1, except that the compound represented by Chemical Formula 3-2 is used instead of the compound represented by Chemical Formula 1-1.

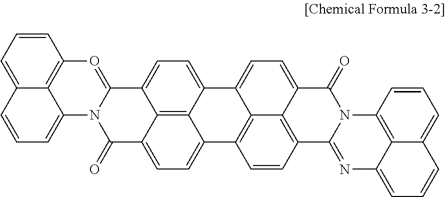

### Comparative Example 1-1

A photoelectric device is manufactured in the same manner as Example 1-1, except that C60 is deposited instead of the compound represented by Chemical Formula 1-1 to form an electron auxiliary layer.

### Comparative Example 1-2

A photoelectric device is manufactured in the same manner as Example 1-2, except that C60 is deposited instead of the compound represented by Chemical Formula 1-1 to form an electron auxiliary layer.

### Comparative Example 1-3A

A photoelectric device is manufactured in the same manner as in Example 1-3, except that the electron auxiliary layer is formed by depositing Chemical Formula C-1 instead of the compound represented by Chemical Formula 1-1.

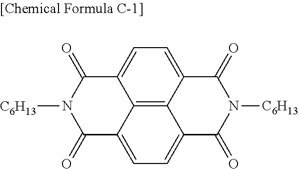

### Comparative Example 1-3B

A photoelectric device is manufactured in the same manner as Example 1-3, except that the electron auxiliary layer is formed by depositing the compound of Chemical Formula C-2 instead of the compound represented by Chemical Formula 1-1.

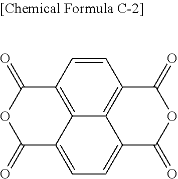 [SMILES: O=C1OC(=O)c2ccc3c4c(ccc1c24)C(=O)OC3=O]

### Comparative Example 1-4

A photoelectric device is manufactured in the same manner as Example 1-4, except that the electron auxiliary layer is formed by depositing the compound of Chemical Formula C-3 instead of the compound represented by Chemical Formula 1-1.

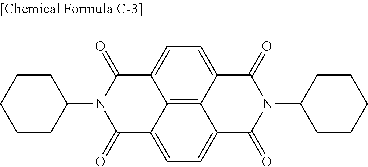 [SMILES: O=C1c2ccc3c4c(ccc(c24)C(=O)N1C1CCCCC1)C(=O)N(C1CCCCC1)C3=O]

### Manufacture of Photoelectric Device II

### Example 1-6

ITO (10 nm), Ag (120 nm), and ITO (50 nm) are sequentially deposited on a glass substrate to form a first electrode with an ITO/Ag/ITO structure. The compound represented by Chemical Formula A-1 of Example 1-1 is deposited on the first electrode to form a 10 nm-thick hole auxiliary layer. Subsequently, on the hole auxiliary layer, a p-type semiconductor (infrared absorbing material) and C60 (n-type semiconductor) represented by Chemical Formula B-2 are co-deposited in a volume ratio (thickness ratio) of 1:3 to form a 200 nm-thick photoelectric conversion layer (active layer). Then, a compound represented by Chemical Formula 1-1 of Example 1-1 is deposited on the photoelectric conversion layer to form a 5 nm-thick electron auxiliary layer, and silver (Ag) is deposited on the photoelectric conversion layer to form a 30 nm-thick second electrode, manufacturing a photoelectric device.

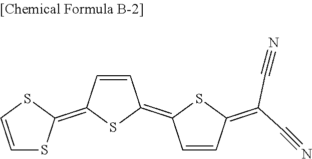 [SMILES: N#CC(C#N)=c1cc/c(=c2/ccc(=C3SC=CS3)s2)s1]

### Example 1-7

ITO (10 nm), Ag (120 nm), and ITO (50 nm) are sequentially deposited on a glass substrate to form a first electrode with an ITO/Ag/ITO structure. The compound represented by Chemical Formula A-1 of Example 1-1 is deposited on the first electrode to form a 10 nm-thick hole auxiliary layer. Subsequently, on the hole auxiliary layer, a p-type semiconductor (infrared absorbing material) and C60 (n-type semiconductor) represented by Chemical Formula B-2 of Example 1-6 are co-deposited in a volume ratio (thickness ratio) of 1:3 to form a 200 nm-thick photoelectric conversion layer (active layer). Then, the compound represented by Chemical Formula 1-1 of Example 1-1 is deposited on the photoelectric conversion layer to form a 5 nm-thick electron auxiliary layer, and ITO is deposited on the photoelectric conversion layer to form a 7 nm-thick second electrode, manufacturing a photoelectric device.

### Example 2-6

A photoelectric device is manufactured in the same manner as Example 1-6, except that the compound represented by Chemical Formula 2-1 is used instead of the compound represented by Chemical Formula 1-1.

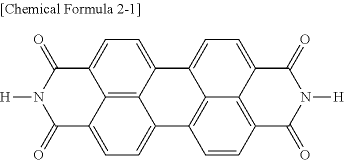 [SMILES: O=C1NC(=O)c2ccc3c4ccc5c6c(ccc(c7ccc1c2c73)c64)C(=O)NC5=O]

### Example 2-7

A photoelectric device is manufactured in the same manner as Example 1-6, except that the compound represented by Chemical Formula 2-2 is used instead of the compound represented by Chemical Formula 1-1.

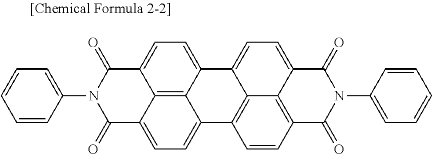 [SMILES: O=C1c2ccc3c4ccc5c6c(ccc(c7ccc(c2c37)C(=O)N1c1ccccc1)c64)C(=O)N(c1ccccc1)C5=O]

### Example 3-6

A photoelectric device is manufactured in the same manner as Example 1-6, except that the compound represented by Chemical Formula 3-1 is used instead of the compound represented by Chemical Formula 1-1.

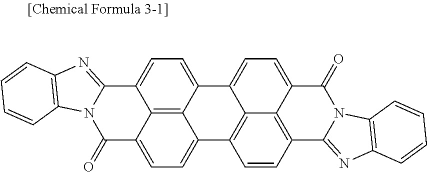 [SMILES: O=c1c2ccc3c4ccc5c6c(ccc(c7ccc(c2c37)c2nc3ccccc3n12)c46)c(=O)n1c2ccccc2nc51]

### Example 3-7A

A photoelectric device is manufactured in the same manner as Example 1-7, except that the compound represented by Chemical Formula 3-1 is used instead of the compound represented by Chemical Formula 1-1.

### Example 3-7B

A photoelectric device is manufactured in the same manner as Example 1-7, except that a 10 nm-thick electron auxiliary layer is formed using the compound represented by Chemical Formula 3-1 instead of the compound represented by Chemical Formula 1-1.

### Example 3-7C

A photoelectric device is manufactured in the same manner as Example 1-7, except that a 20 nm-thick electron auxiliary layer is formed using the compound represented by Chemical Formula 3-1 instead of the compound represented by Chemical Formula 1-1.

### Example 3-7D

A photoelectric device is manufactured in the same manner as Example 1-7, except that a 30 nm-thick electron auxiliary layer is formed using the compound represented by Chemical Formula 3-1 instead of the compound represented by Chemical Formula 1-1.

### Example 3-7E

A photoelectric device is manufactured in the same manner as Example 1-7, except that a 40 nm-thick electron auxiliary layer is formed using the compound represented by Chemical Formula 3-1 instead of the compound represented by Chemical Formula 1-1.

### Example 3-7F

A photoelectric device is manufactured in the same manner as Example 1-7, except that a 50 nm-thick electron auxiliary layer is formed using the compound represented by Chemical Formula 3-1 instead of the compound represented by Chemical Formula 1-1.

### Example 3-8

A photoelectric device is manufactured in the same manner as Example 1-6, except that the compound represented by Chemical Formula 3-2 is used instead of the compound represented by Chemical Formula 1-1.

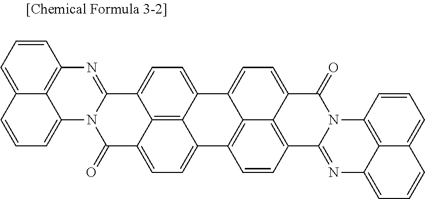 [SMILES: O=c1c2ccc3c4ccc5c6c(ccc(c7ccc(c2c37)c2nc3cccc7cccc(c73)n12)c46)c(=O)n1c2cccc3cccc(nc51)c32]

### Comparative Example 1-6

A photoelectric device is manufactured in the same manner as Example 1-6, except that C60 is deposited instead of the compound represented by Chemical Formula 1-1 to form an electron auxiliary layer.

### Comparative Example 1-7

A photoelectric device is manufactured in the same manner as Example 1-7, except that C60 is deposited instead of the compound represented by Chemical Formula 1-1 to form an electron auxiliary layer.

### Comparative Example 2-6

A photoelectric device is manufactured in the same manner as in Example 1-6, except that the electron auxiliary layer is formed by depositing the compound of Chemical Formula C-4 instead of the compound represented by Chemical Formula 1-1.

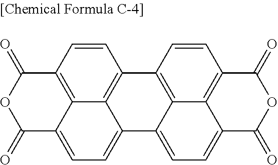 [SMILES: O=C1OC(=O)c2ccc3c4ccc5c6c(ccc(c7ccc1c2c73)c64)C(=O)OC5=O]

### Evaluation I: Evaluation of Absorption Spectra and Photoelectric Conversion Efficiency of Photoelectric Devices

The photoelectric conversion efficiency of photoelectric devices is evaluated from the EQE maximum value (EQEₘₐₓ) in the EQE spectrum, and is evaluated using the Incident Photon to Current Efficiency (IPCE) method in the 800 nm to 1500 nm wavelength range at 3 V.

The results are shown in Table 1.

TABLE 1

| | λ_{peak, EQE} (nm) | EQEₘₐₓ (−3 V) (%) |
|---|---|---|
| Example 1-1 | 1210 | 28 |
| Example 2-1 | 1210 | 28 |
| Example 1-2 | 1205 | 15 |
| Example 1-3 | 1260 | 10 |
| Example 1-4 | 1135 | 34 |
| Example 1-5 | 1305 | 10 |
| Example 1-6 | 1100 | 20 |
| Example 2-2 | 1310 | 9 |
| Comparative | 1170 | 1 |
| Example 2-6 | | |
| Comparative | 1260 | 3 |
| Example 1-3A | | |
| Comparative | 1260 | 2 |
| Example 1-3B | | |

*λ_{peak, EQE}: peak wavelength of EQE spectrum
* EQEₘₐₓ: EQE maximum value at the peak wavelength of the EQE spectrum

Referring to Table 1, the photoelectric devices according to Examples exhibit maximum EQE values in the infrared absorption wavelength range and excellent photoelectric conversion efficiency compared to the photoelectric device according to Comparative Examples.

### Evaluation II: Evaluation of Dark Current of Photovoltaic Devices

The dark current of the photoelectric device is evaluated from a dark current density by measuring each current of the devices with a current-voltage evaluation equipment (K4200 parameter analyzer, Keithley) under a dark room condition and dividing it by a unit pixel area (0.04 cm²), and herein, the dark current density is evaluated from a current flowing when a reverse bias of −3 V is applied thereto.

The results are shown in Table 2.

TABLE 2

| | Dark current (h/s/μm²) @−3 V |
|---|---|
| Example 1-1 | 55k |
| Example 2-1 | 52k |
| Example 1-2 | 27k |
| Example 1-6 | 37k |
| Example 3-6 | 26k |
| Comparative Example 1-1 | 60k |
| Comparative Example 1-2 | 84k |

Referring to Table 2, the photoelectric devices according to Examples exhibit a lower dark current than the photoelectric devices according to Comparative Examples.

With respect to the photoelectric devices according to Example 3-7A, Example 3-7, Example 3-70, Example 3-7D, Example 3-7E, and Example 3-7F manufactured by varying the thickness of the electronic auxiliary layer, the dark currents are evaluated and shown in Table 3.

For comparison, the results of the photoelectric device according to Example 1-7 without an electron auxiliary layer (Control Example 1-7) are also shown in Table 3.

TABLE 3

| | Thickness of | |
|---|---|---|
| | electron auxiliary | Dark current |
| | layer (nm) | (h/s/μm²) @−3 V |
| Control Example 1-7 | 0 | 78k |
| Example 3-7A | 5 | 26k |
| Example 3-7B | 10 | 27k |
| Example 3-7C | 20 | 19k |
| Example 3-7D | 30 | 9.7k |
| Example 3-7E | 40 | 8.5k |
| Example 3-7F | 50 | 9.3k |

Referring to Table 3, dark currents of the photoelectric devices according to Example 3-7A, Example 3-71, Example 3-70C, Example 3-7D, Example 3-7E, and Example 3-7F are significantly reduced compared to the photoelectric device according to Control Example 1-7.

### Evaluation III: Evaluation of Thermal Stability of Photoelectric Devices

The photoelectric conversion efficiency (EQEₘₐₓ (−3V)) and dark current (−3V) of the photoelectric devices according to Examples and Comparative Examples are measured at room temperature (25° C.) 150° C., 160° C., 170° C., and 180° C. after being held at such temperatures for 1 hour (1 h), and the results are shown in Tables 4 and 5.

TABLE 4

| | Room | | | | |
|---|---|---|---|---|---|
| | temper- | | | | |
| EQEₘₐₓ | ature | 150° C., | 160° C., | 170° C., | 180° C., |
| (−3 V) | (25° C.) | 1 h | 1 h | 1 h | 1 h |
| Comparative | 1 | 0.97 | 0.87 | 0.86 | 0.83 |
| Example 1-6 | | | | | |
| Example 1-6 | 1 | 1.02 | 1.04 | 1.03 | 1.00 |
| Example 3-6 | 1 | 0.97 | 0.96 | 0.93 | 0.98 |
| Example 3-8 | 1 | 1.00 | 1.01 | 0.93 | 0.90 |

TABLE 5

| | Room | | | | |
|---|---|---|---|---|---|
| Dark current | temper- | | | | |
| (h/s/μm²) | ature | 150° C., | 160° C., | 170° C., | 180° C., |
| (−3 V) | (25° C.) | 1 h | 1 h | 1 h | 1 h |
| Comparative | 43k | 49k | 42k | 47k | 54k |
| Example 1-6 | | | | | |
| Example 1-6 | 37k | 40k | 43k | 41k | 43k |
| Example 3-6 | 37k | 35k | 35k | 35k | 37k |
| Example 3-8 | 21k | 22k | 20k | 23k | 29k |

Each value in Table 4 is a normalized value based on the EQE value at room temperature.

Referring to Tables 4 and 5, the EQE and dark current values of the photoelectric devices according to Examples 1-6, 3-6, and 3-8 remain stable compared to those of the photoelectric devices according to Comparative Examples 1-6 even after heat treatment. From these results, the photoelectric devices according to Examples 1-6, 3-6, and 3-8 have superior thermal stability compared to the photoelectric devices according to Comparative Examples 1-6.

### Evaluation IV: Evaluation of Charge Mobility of Photoelectric Devices

Charge mobility is evaluated by measuring TDCF (time-delayed collection field) mobility. The photoelectric devices according to Examples and Comparative Examples are irradiated by a laser of 550 nm (a pulse width: 6 nm) with a light source, and then, a bias (V) voltage is applied thereto to measure a photocurrent.

Equation 1 is used to obtain the TDCF mobility.

Charge mobility=(T)²/(t*V) [Equation 1]

In Equation 1,
T is a thickness of a photoelectric conversion layer (active layer), t is time when the photo current is maximized, and V is the bias voltage.

The results of Comparative Example 1-7, Example 1-7, and Example 3-7A are shown in Table 6. For comparison, the results of the photoelectric device without an electron auxiliary layer (Control Example 1-7) in the photoelectric device according to Example 1-7 are shown together in Table 6.

TABLE 6

| | Charge mobility (cm²/V · s) |
|---|---|
| Control Example 1-7 | 5.29 × 10⁻⁶ |
| Comparative Example 1-7 | 6.42 × 10⁻⁶ |
| Example 1-7 | 8.66 × 10⁻⁶ |
| Example 3-7A | 9.23 × 10⁻⁶ |

Referring to Table 6, the charge mobility of the photoelectric devices according to Examples 1-7 and 3-7A is superior to that of the photoelectric devices according to Comparative Example 1-7 and Control Example 1-7.

While the inventive concepts have been described in connection with what is presently considered to be practical example embodiments, it is to be understood that the inventive concepts are not limited to such example embodiments. On the contrary, the inventive concepts are intended to cover various modifications and equivalent arrangements included within the spirit and scope of the appended claims.

### DESCRIPTION OF SYMBOLS

100: photoelectric device
110: first electrode
120: second electrode
130: active layer
140: hole auxiliary layer
150: electron auxiliary layer
40: semiconductor substrate
60, 80: insulation layer
65, 85: trench
200: substrate
220: first photodiode
230: second photodiode
300, 400, 500, 600: sensor

What is claimed is:

1. A photoelectric device, comprising:
a first electrode,
a second electrode facing the first electrode,
an active layer between the first electrode and the second electrode, and
an electron auxiliary layer between the second electrode and the active layer,
wherein the electron auxiliary layer includes any one compound selected from compounds represented by Chemical Formulas 1 to 4 and any combination thereof: 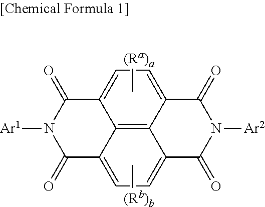
wherein, in Chemical Formula 1,
Ar¹ and Ar² are each independently a substituted or unsubstituted C10 to C30 aryl group or a substituted or unsubstituted C2 to C30 heteroaryl group,
R^{a} and R^{b} are each independently hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a and b are each independently integers of 1 or 2, 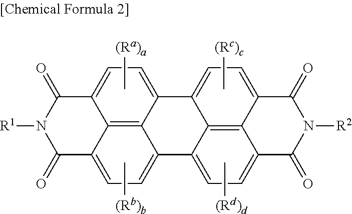
wherein, in Chemical Formula 2,
R¹ and R² are each independently hydrogen, deuterium, a substituted or unsubstituted C6 to C30 aryl group, or a substituted or unsubstituted C3 to C30 heteroaryl group,
R^{a} to R^{d} are each independently hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a to d are each independently an integer of 1 or 2, 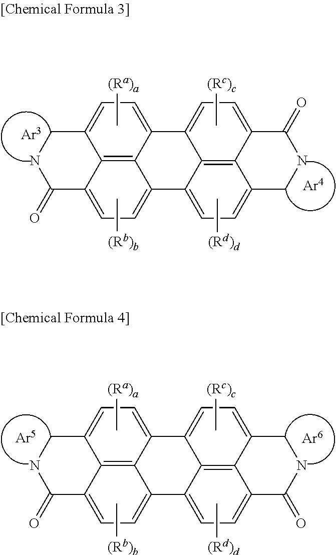
wherein, in Chemical Formulas 3 and 4,
Ar³ to Ar⁶ are each independently hydrogen, a substituted or unsubstituted C6 to C30 arene group, or a substituted or unsubstituted C3 to C30 heteroarene group,
R^{a} to R^{d} are each independently hydrogen, deuterium, a substituted or unsubstituted C1 to C30 alkyl group, a substituted or unsubstituted C2 to C30 alkenyl group, a substituted or unsubstituted C2 to C30 alkynyl group, a substituted or unsubstituted C1 to C30 alkoxy group, a substituted or unsubstituted C6 to C20 aryl group, a substituted or unsubstituted C6 to C20 aryloxy group, a substituted or unsubstituted C3 to C20 heteroaryl group, a substituted or unsubstituted C3 to C20 cycloalkyl group, a substituted or unsubstituted C3 to C20 heterocycloalkyl group, or any combination thereof, and
a to d are each independently an integer of 1 or 2.

2. The photoelectric device of claim 1, wherein
Ar¹ and Ar² are each independently a functional group represented by any one of Chemical Formulas 5A to 5K: 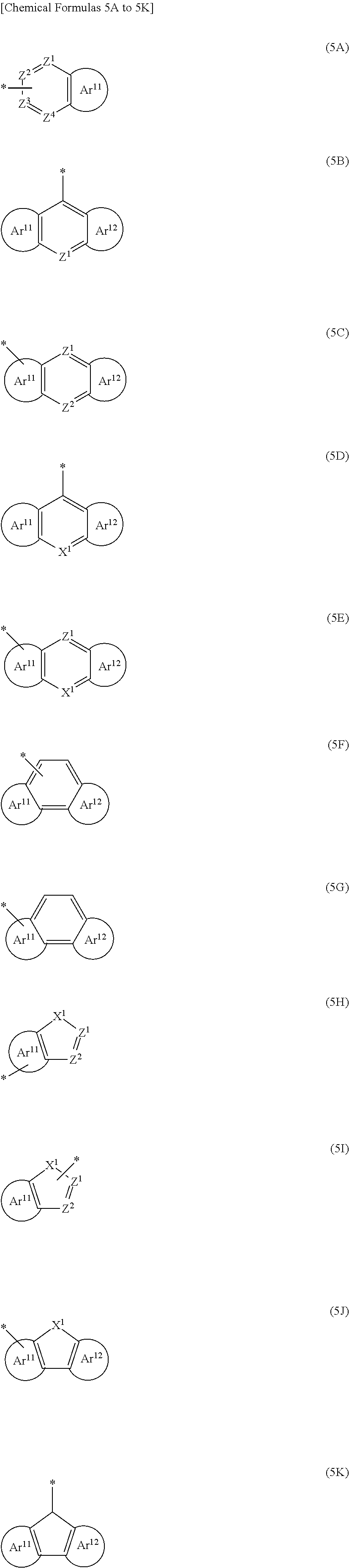
wherein, in Chemical Formulas 5A to 5K,
X¹ is O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z⁴ are each independently CR^{x} or N, wherein R^{x} is hydrogen, deuterium, A C1 to C10 alkyl group, a C6 to C14 aryl group, a C3 to C12 heteroaryl group, or any combination thereof, provided that in Chemical Formula 5A, one of Z¹ to Z⁴ is CR^{x} wherein R^{x} is a single bond, and in Chemical Formula 51, one of Z¹ and Z² is CR^{x} wherein R^{x} is a single bond,
Ar¹¹ and Ar¹² are each independently a substituted or unsubstituted C6 to C20 arene group or a substituted or unsubstituted C2 to C20 heteroarene group,
at least one hydrogen of each aromatic ring or heteroaromatic ring is present or is replaced by deuterium, a C1 to C10 alkyl group, a C1 to C10 alkoxy group, a C6 to C10 aryl group, a C6 to C10 aryloxy group, or any combination thereof,
—CH₂— of each aromatic ring or heteroaromatic ring is present or is replaced by —N—, and
* is a linking point with Chemical Formula 1.

3. The photoelectric device of claim 1, wherein
in Chemical Formula 1, Ar¹ and Ar² are each independently a functional group represented by one of Chemical Formulas 6A to 6I: 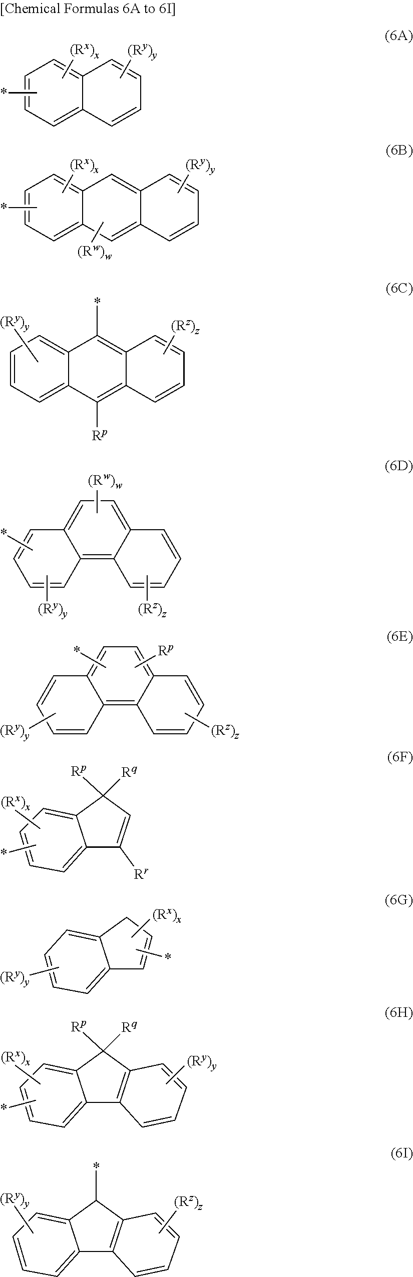
wherein, in Chemical Formulas 6A to 6I,
R^{x}, R^{y}, R^{z}, R^{w}, R^{p}, R^{q}, and R^{r} are each independently hydrogen, deuterium, a C1 to C10 alkyl group, a C6 to C14 aryl group, a C3 to C12 heteroaryl group, or any combination thereof, wherein R^{p} and R^{q} are each independently present or linked to each other to form a spiro structure,
x is an integer from 0 to 3,
y and z are each independently integers from 0 to 4,
w is an integer from 0 to 2, and
* is a linking point with Chemical Formula 1.

4. The photoelectric device of claim 1, wherein
in Chemical Formula 1, Ar¹ and Ar² are each independently a functional group represented by one of Chemical Formulas 7A to 7Q: 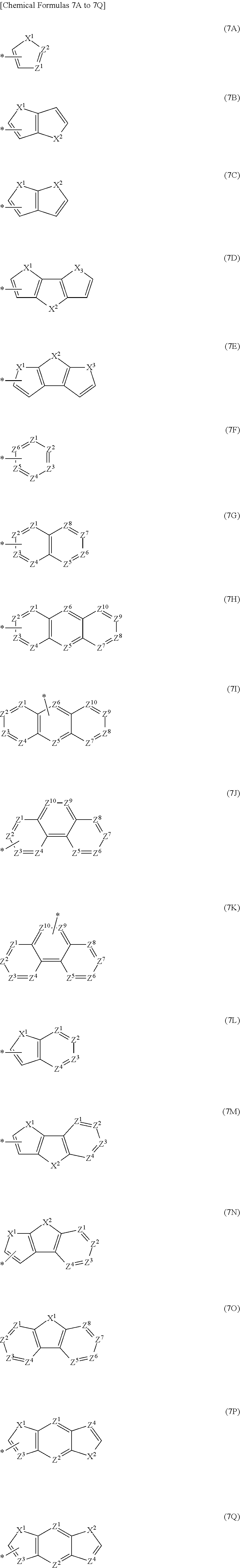
wherein, in Chemical Formulas 7A to 7Q,
X¹, X², and X³ are each independently O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z¹⁰ are each independently CR^{x} or N, wherein R^{x} is hydrogen, deuterium, a C1 to C10 alkyl group, a C6 to C14 aryl group, a C3 to C12 heteroaryl group, or any combination thereof, provided that when in Chemical Formula 7F, one of Z¹ to Z⁶ is a linking point with Chemical Formula 1, one of Z¹ to Z⁶ is CR^{x} wherein R^{x} is a single bond; when in Chemical Formulas 7G, 7H, 7J, and 7O, one of Z¹ to Z⁴ is a linking point with Chemical Formula 1, one of Z¹ to Z⁴ is CR^{x} wherein R^{x} is a single bond; when in Chemical Formula 71, one of Z⁵ to Z⁶ is a linking point with Chemical Formula 1, one of Z⁵ and Z⁶ is CR^{x} wherein R^{x} is a single bond; when in Chemical Formula 7K, one of Z⁹ and Z¹⁰ is a linking point with Chemical Formula 1, one of Z⁹ and Z¹⁰ is CR^{x} wherein R^{x} is a single bond; when in Chemical Formulas 7P and 7Q, Z³ is a linking point with Chemical Formula 1, Z³ is CR^{x} wherein R^{x} is a single bond, at least one hydrogen of each aromatic ring or heteroaromatic ring is optionally replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring is present or is replaced by —N—, and
* is a linking point with Chemical Formula 1.

5. The photoelectric device of claim 1, wherein
in Chemical Formula 1, Ar¹ and Ar² are each independently a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyrimidinyl group, a substituted or unsubstituted quinolinyl group, a substituted or unsubstituted isoquinolinyl group, a substituted or unsubstituted quinoxalinyl group, a substituted or unsubstituted quinazolinyl group, a substituted or unsubstituted phenanthrolyl group, a substituted or unsubstituted pyrrolyl group, a substituted or unsubstituted thienyl group, a substituted or unsubstituted indolyl group a substituted or unsubstituted benzimidazolyl group, a substituted or unsubstituted benzthiazolyl group, or a substituted or unsubstituted carbazolyl group.

6. The photoelectric device of claim 1, wherein
in Chemical Formula 2, R¹ and R² are each independently a functional group represented by one of Chemical Formulas 5A to 5L: 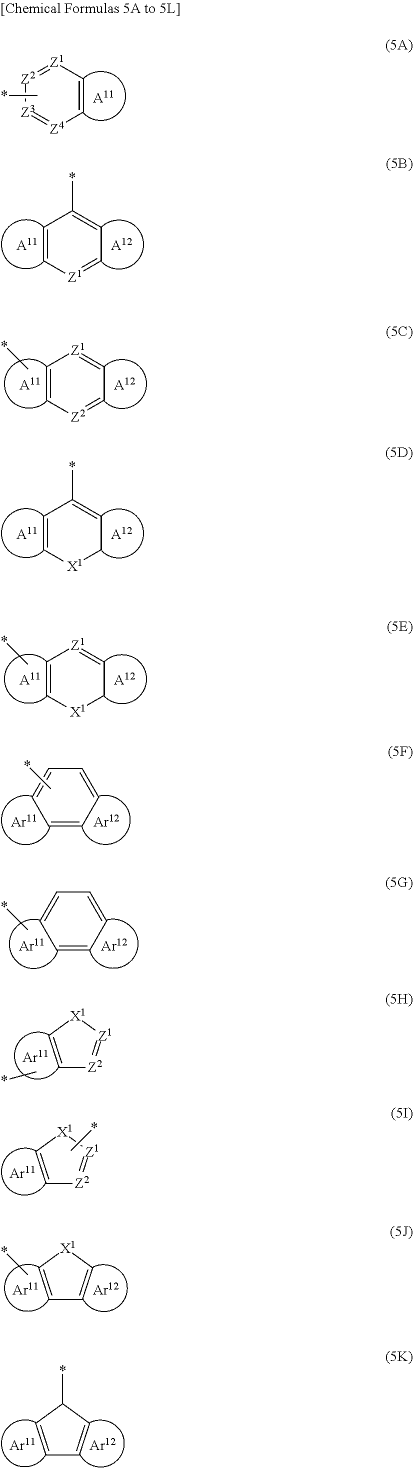 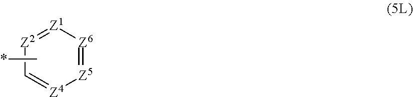
wherein, in Chemical Formulas 5A to 5L,
X¹ and X² are each independently O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z⁶ are each independently CR^{x} or N, wherein R^{x} is hydrogen, deuterium, a C1 to C10 alkyl group, a C6 to C14 aryl group, a C3 to C12 heteroaryl group, or any combination thereof, provided that in Chemical Formula 5A, one of Z¹ to Z⁴ is CR^{x} wherein R^{x} is a single bond, in Chemical Formula 51, one of Z¹ and Z² is CR^{x} wherein R^{x} is a single bond, and in Chemical Formula 5L, one of Z¹ to Z⁶ is CR^{x} wherein R^{x} is a single bond,
Ar¹¹ and Ar¹² are each independently a substituted or unsubstituted C6 to C20 arene group or a substituted or unsubstituted C2 to C20 heteroarene group,
at least one hydrogen of each aromatic ring or heteroaromatic ring is present or is replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring is present or is replaced by —N—, and
* is a linking point with Chemical Formula 2.

7. The photoelectric device of claim 1, wherein
in Chemical Formula 2, R¹ and R² are each independently a functional group represented by one of Chemical Formulas 6A to 6J: 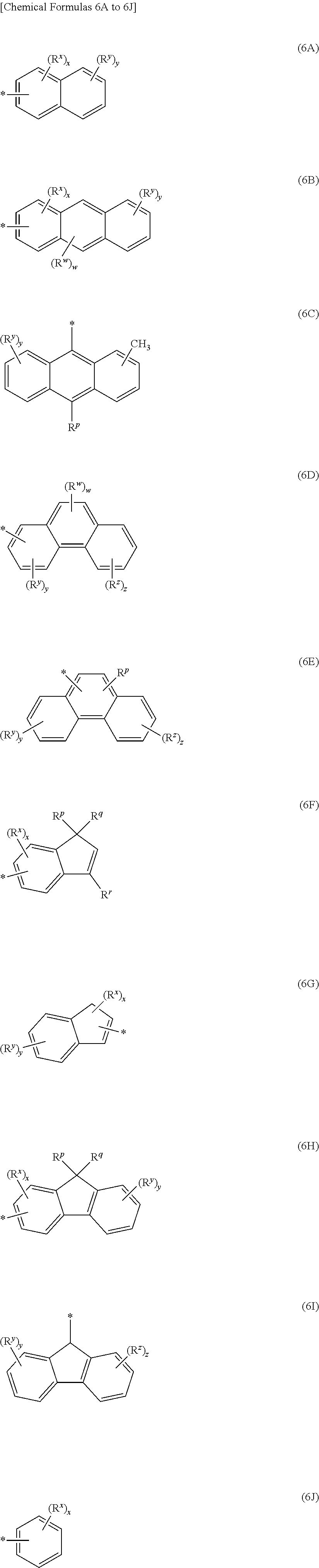
wherein, in Chemical Formulas 6A to 6J,
R^{x}, R^{y}, R^{z}, R^{w}, R^{p}, R^{q}, and R^{r} are each independently hydrogen, deuterium, a C1 to C10 alkyl group, a C6 to C14 aryl group, a C3 to C12 heteroaryl group, or any combination thereof, wherein R^{p} and R^{q} are each independently present or linked to each other to form a spiro structure,
x is an integer from 0 to 3,
y and z are each independently integers from 0 to 4,
w is an integer from 0 to 2, and
* is a linking point with Chemical Formula 2.

8. The photoelectric device of claim 1, wherein
in Chemical Formula 2, R¹ and R² are each independently a functional group represented by one of Chemical Formulas 7A to 7Q: 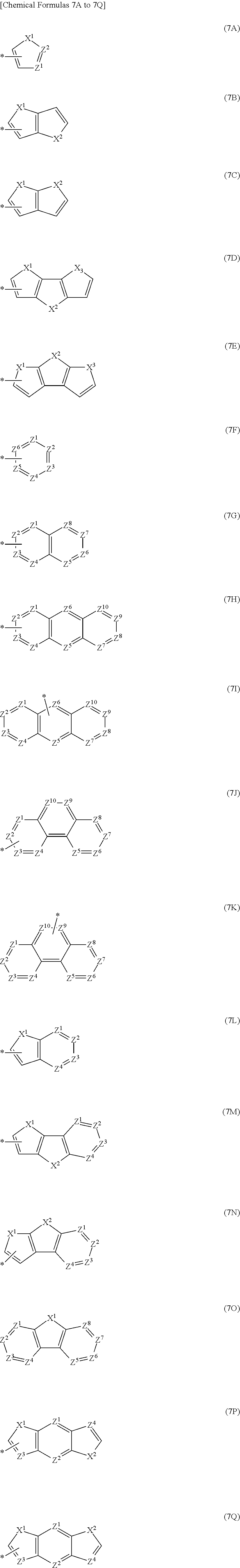
wherein, in Chemical Formulas 7A to 7Q,
X¹, X², and X³ are each independently O, S, Se, Te, S(═O), S(═O)₂, NR^{a}, SiR^{b}R^{c}, or GeR^{d}R^{e}, wherein R^{a}, R^{b}, R^{c}, R^{d}, and R^{e} are each independently hydrogen, deuterium, a C1 to C10 alkyl group, a C6 to C14 aryl group, a C3 to C12 heteroaryl group, or any combination thereof,
Z¹ to Z¹⁰ are each independently CR^{x} or N, wherein R^{x} is hydrogen, deuterium, a C1 to C10 alkyl group, a C6 to C14 aryl group, a C3 to C12 heteroaryl group, or any combination thereof, provided that when in Chemical Formula 7F, one of Z¹ to Z⁶ is a linking point with Chemical Formula 2, one of Z¹ to Z⁶ is CR^{x} wherein R^{x} is a single bond; when in Chemical Formulas 7G, 7H, 7J, and 70, one of Z¹ to Z⁴ is a linking point with Chemical Formula 2, one of Z¹ to Z⁴ is CR^{x} wherein R^{x} is a single bond; when in Chemical Formula 71, one of Z⁵ to Z⁶ is a linking point with Chemical Formula 2, one of Z⁵ and Z⁶ is CR^{x} wherein R^{x} is a single bond; when in Chemical Formula 7K, one of Z⁹ and Z¹⁰ is a linking point with Chemical Formula 2, one of Z⁹ and Z¹⁰ is CR^{x} wherein R^{x} is a single bond; when in Chemical Formulas 7P and 7Q, Z³ is a linking point with Chemical Formula 2, Z³ is CR^{x} wherein R^{x} is a single bond,
at least one hydrogen of each aromatic ring or heteroaromatic ring is present or is replaced by deuterium, a C1 to C10 alkyl group, a C1 to C10 alkoxy group, a C6 to C10 aryl group, a C6 to C10 aryloxy group, or any combination thereof,
at least one —CH₂— of each aromatic ring or heteroaromatic ring is present or is replaced by —N—, and
* is a linking point with Chemical Formula 2.

9. The photoelectric device of claim 1, wherein
in Chemical Formula 2, R¹ and R² are each independently a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyrimidinyl group, a substituted or unsubstituted quinolinyl group, a substituted or unsubstituted isoquinolinyl group, a substituted or unsubstituted quinoxalinyl group, a substituted or unsubstituted quinazolinyl group, a substituted or unsubstituted phenanthrolyl group, a substituted or unsubstituted pyrrolyl group, a substituted or unsubstituted thienyl group, a substituted or unsubstituted indolyl group a substituted or unsubstituted benzimidazolyl group, a substituted or unsubstituted benzthiazolyl group, or a substituted or unsubstituted carbazolyl group.

10. The photoelectric device of claim 1, wherein
the compound of Chemical Formula 3 is a compound represented by any one of Chemical Formulas 3-1 to 3-9. 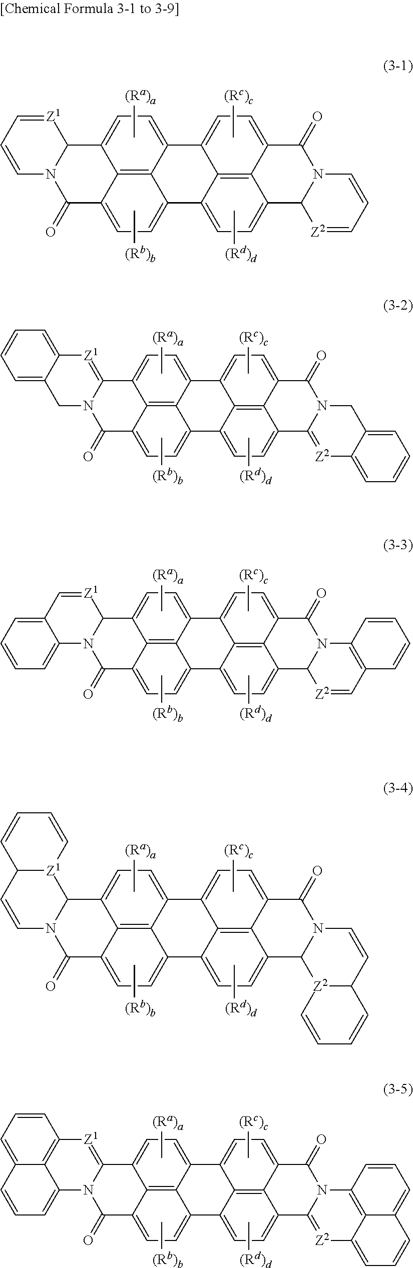 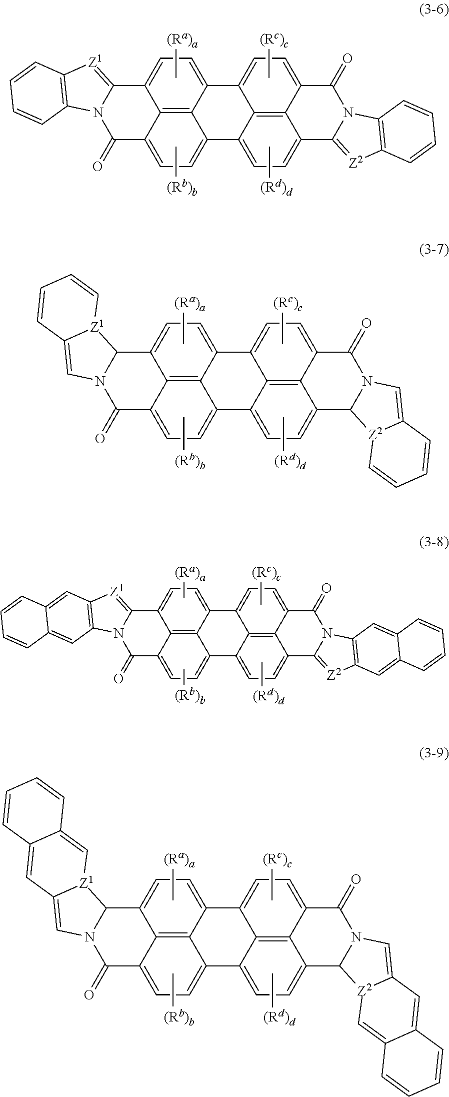
wherein, in Chemical Formula 3-1 to 3-9,
R^{a}, R^{b}, R^{c}, R^{d}, a, b, c, and d are the same as R^{a}, R^{b}, R^{c}, R^{d}, a, b, c, and d, respectively, in Chemical Formula 3,
Z¹ and Z² are each independently CR^{x} or N, wherein R^{x} is hydrogen, deuterium, A C1 to C10 alkyl group, a C6 to C14 aryl group, a C3 to C12 heteroaryl group, or any combination thereof,
at least one hydrogen of each aromatic ring or heteroaromatic ring is present or is replaced by deuterium, a C1 to C10 alkyl group, a C1 to C10 alkoxy group, a C6 to C10 aryl group, a C6 to C10 aryloxy group, or any combination thereof, and
at least one —CH₂— of each aromatic ring or heteroaromatic ring is present or is replaced by —N—.

11. The photoelectric device of claim 1, wherein
the compound of Chemical Formula 4 is a compound represented by any one of Chemical Formulas 4-1 to 4-9: 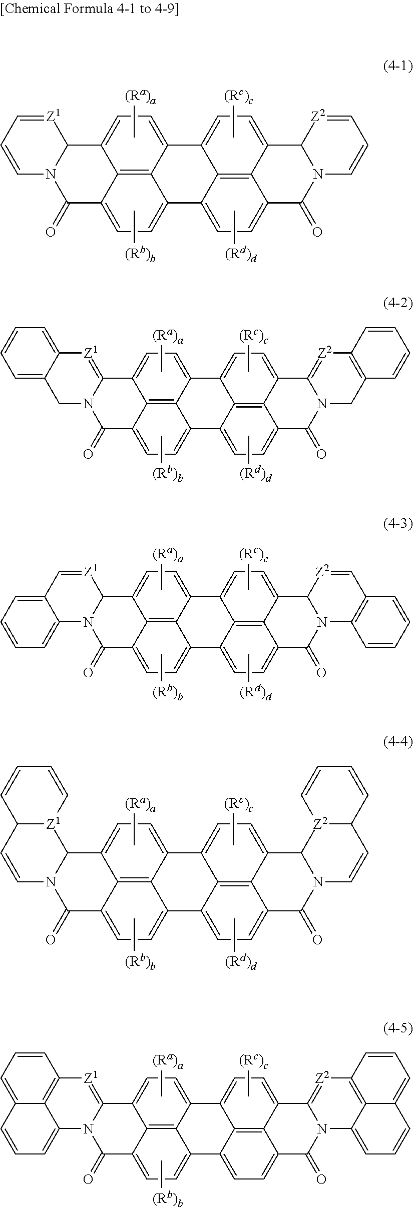 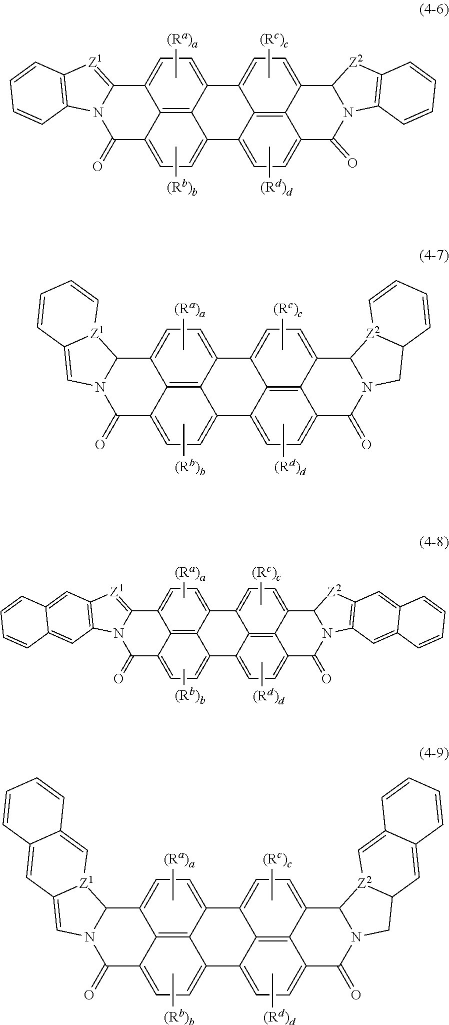
wherein, in Chemical Formulas 4-1 to 4-9,
R^{a}, R^{b}, R^{c}, R^{d}, a, b, c, and d are the same as R^{a}, R^{b}, R^{c}, R^{d}, a, b, c, and d, respectively, in Chemical Formula 4,
Z¹ and Z² are each independently CR^{x} or N, wherein R^{x} is hydrogen, deuterium, A C1 to C10 alkyl group, a C6 to C14 aryl group, a C3 to C12 heteroaryl group, or any combination thereof,
at least one hydrogen of each aromatic ring or heteroaromatic ring is present or is replaced by deuterium, a C1 to C10 alkyl group, a C1 to C10 alkoxy group, a C6 to C10 aryl group, a C6 to C10 aryloxy group, or any combination thereof, and
at least one —CH₂— of each aromatic ring or heteroaromatic ring is present or is replaced by —N—.

12. The photoelectric device of claim 1, wherein
the electron auxiliary layer is an electron transport layer.

13. The photoelectric device of claim 1, wherein
the active layer is an infrared photoelectric conversion layer that is configured to absorb light in at least a portion of an infrared wavelength range and convert the absorbed light into an electrical signal.

14. The photoelectric device of claim 1, wherein
the active layer includes a metal phthalocyanine complex, a metal naphthalocyanine complex, or a compound including a quinoid moiety.

15. The photoelectric device of claim 1, wherein
the photoelectric device further includes a hole auxiliary layer between the first electrode and the active layer.

16. The photoelectric device of claim 1, wherein
the first electrode includes a reflective layer, and the second electrode includes a semi-transmissive layer that forms a microcavity structure with the reflective layer of the first electrode.

17. The photoelectric device of claim 1, wherein
the first electrode has a stacked structure of a reflective layer/light-transmitting layer or a first light-transmitting layer/reflective layer/second light-transmitting layer.

18. A sensor comprising the photoelectric device according to claim 1.

19. An electronic device comprising the photoelectric device according to claim 1.
